(19) United States
(12) Patent Application Publication
(10) Pub. No.: US 2024/0242871 A1
(43) Pub. Date: Jul. 18, 2024

(54) MAGNETIC APPARATUSES WITH TWO-SURFACE CONDUCTIVE CONTACTS, POWER MODULES, MULTIPLE-SWITCH ENCAPSULATIONS, AND POWER SUPPLY SYSTEMS

(71) Applicant: SHANGHAI METAPWR ELECTRONICS CO. , LTD, Shanghai (CN)

(72) Inventor: Jianhong ZENG, Shanghai (CN)

(73) Assignee: SHANGHAI METAPWR ELECTRONICS CO. , LTD, Shanghai (CN)

(21) Appl. No.: 18/408,549

(22) Filed: Jan. 9, 2024

(30) Foreign Application Priority Data
Jan. 16, 2023 (CN) 202310078187.6

(51) Int. Cl. H01F 27/28; H01F 27/24; H01F 27/29; H01F 30/06; H02M 7/00

(52) U.S. Cl. CPC H01F 27/2804; H01F 27/24; H01F 27/292; H01F 30/06; H02M 7/003; H01F 2027/2819

(57) ABSTRACT

A magnetic apparatus with two-surface conductive contacts includes a magnetically permeable core and a winding substrate. Windings are arranged in the winding substrate to convert electric signal vertically from AC terminals to DC terminals. A power module includes the magnetic apparatus configured as a middle assembly, an upper assembly including power semiconductor devices, and power pins. A plurality of switches may be encapsulated together sharing a public source pin. A power supply system including a power module and a chip may be installed across a system board and electrically connected through vias with power supply lines overpassing a signal-via region.

### CROSS-REFERENCE TO RELATED APPLICATIONS

This application claims the priority benefit of Chinese patent application serial no. 202310078187.6, filed on Jan. 16, 2023. The entirety of the above-mentioned patent application is hereby incorporated by reference herein and made a part of this specification.

### BACKGROUND

The statements in this section merely provide background information related to the present application and do not necessarily constitute prior art.

With the development of artificial intelligence, the power requirements for intelligent data processing chips, such as GPUs, CPUs, NPUs, etc. (collectively referred to as xPUs), are increasingly high. This has led to a significant increase in server power, and the output voltage of servers is gradually shifting from 12V to 48V. Meanwhile, the working voltage of xPUs is becoming lower with technological advancements. Therefore, the difference in supply voltage is increasing, making a two-stage buck circuit architecture progressively mainstream.

To accommodate the traditional 12V supply, the first-stage buck circuit typically converts the 48V to a 12V intermediate bus voltage, and then the second-stage buck circuit converts this 12V intermediate bus voltage to a low voltage to power the xPU. However, as the demand for higher supply frequencies for xPUs increases, the frequency of the second-stage buck circuit with a 12V input is limited, usually operating at less than 2 MHz. Consequently, further reducing the intermediate bus voltage becomes a new trend, for example, to 5V or even 3.3V. This allows the second-stage buck circuit to operate at frequencies higher than 2 MHz, 4 MHz, or even above 10 MHz.

### SUMMARY

In general, one aspect features an apparatus comprises:
a magnetically permeable core and a winding substrate;
wherein the winding substrate is provided with a first side surface and a second side surface which are opposite to each other, and the winding substrate is further provided with a first contact surface and a second contact surface which are opposite to each other;
wherein the first contact surface and the second contact surface are located between the first side surface and the second side surface; at least two AC terminals are arranged on the first contact surface; at least one DC terminal is arranged on the second contact surface; at least three penetrate structures are formed in the winding substrate and configured as magnetically-permeable-core holes, each of the penetrate structures penetrating from the first side surface to the second side surface;
parts of the winding substrate between the magnetically-permeable-core holes are configured as winding regions;
wherein the magnetically permeable core comprises at least three core legs and two core plates; the core plates are affixed to the first side surface or the second side surface respectively; the core legs are connected to the core plates through the selected magnetically-permeable-core holes;
wherein at least two windings are arranged in the winding substrate, the windings passing through the selected winding region or selected winding regions;
wherein one end of each of the windings is electrically connected with the selected AC terminal; and
wherein another end of each of the windings is electrically connected with the selected DC terminal.

Implementations of the apparatus may include one or more of following features. At least two winding regions are provided, and at least two of the windings are configured as low-voltage windings, each of the low-voltage windings passing through one selected winding region; a high-voltage winding is further configured in the winding substrate, the high-voltage winding passing through each of the selected winding regions through which the low-voltage windings pass; and
wherein the AC terminals include two high-voltage AC terminals and at least one low-voltage AC terminal; two ends of the high-voltage winding are electrically connected with the high-voltage AC terminals, and two ends of each of the low-voltage windings are electrically connected with the selected low-voltage AC terminal and the selected the DC terminal respectively.

Implementations of the apparatus may include one or more of following features. The high-voltage winding passes through at least one of the winding regions multiple times in the same direction, and the number of turns of the high-voltage winding is greater than 1.

Implementations of the apparatus may include one or more of following features. The low-voltage windings are in an even number and are arranged in pairs, the low-voltage windings in each of the pairs respectively pass through the two winding regions separated by one of the core legs, and the low-voltage windings in each of the pairs are connected to one selected DC terminal.

Implementations of the apparatus may include one or more of following features. At least two winding substrates are provided and are arranged side by side, the magnetically-permeable-core holes in one winding substrate are aligned with the magnetically-permeable-core holes in another winding substrate, and the core legs pass through the aligned magnetically-permeable-core holes;

wherein two low-voltage windings are configured in each of the winding substrates, the low-voltage windings in each of winding substrates respectively pass through the two winding regions separated by one of the core legs, and the low-voltage windings in each of winding substrates are connected to one selected DC terminal; and
wherein the high-voltage winding in one of the winding substrates is electrically connected in series or in parallel to the high-voltage winding in another of the winding substrates.

Implementations of the apparatus may include one or more of following features. At least two penetrate structures are further formed in the winding substrate and configured as output-inductor holes, each of the penetrate structures penetrating from the first side surface to the second side surface; parts of the winding substrate between the output-inductor holes are configured as output-inductor-winding regions; each of the low-voltage windings passes through the winding regions, passes through the output-inductor-winding region, and is electrically connected with the DC terminal; and
wherein the magnetically permeable core further comprises an output inductor core, the output inductor core comprises output inductor core legs, and the output inductor core legs pass through the selected output-inductor holes.

Implementations of the apparatus may include one or more of following features. A resonant-inductor hole is further formed in the winding substrate, the magnetically permeable core further comprises a resonant inductor core leg, the resonant inductor core leg passes through the resonant-inductor hole, and at least one part of the high-voltage winding is configured to wind around the resonant inductor core leg by at least one turn.

Implementations of the apparatus may include one or more of following features. At least one electric connection region is further provided in the winding substrate, conductive connectors are configured in the electric connection region, first additional terminals are arranged on the first contact surface and second additional terminals are arranged on the second contact surface, and the first additional terminals are electrically connected with the selected second additional terminals through the conductive connectors; and
wherein the electric connection region is configured to transmit high-voltage DC input signals, and/or detection signals, and/or control signals, and/or auxiliary power supply signals between the first contact surface and the second contact surface,
and/or, the electric connection region is configured to extend ground pins between the second contact surface and the first contact surface.

Implementations of the apparatus may include one or more of following features. Each of the windings passes through the selected winding regions multiple times in the same direction.

In general, another aspect features a power module, comprising:
a middle assembly comprising a magnetically permeable core and a winding substrate;
an upper assembly comprising an upper substrate and one or more power semiconductor devices, wherein the power semiconductor device or each of the power semiconductor devices is arranged on the upper substrate, and
power pins comprising ground pins, input positive pins and output positive pins;
wherein the winding substrate is provided with a first side surface and a second side surface which are opposite to each other, and the winding substrate is further provided with a first contact surface and a second contact surface which are opposite to each other;
wherein the first contact surface and the second contact surface are located between the first side surface and the second side surface; at least two AC terminals are arranged on the first contact surface; at least one DC terminal is arranged on the second contact surface; at least three penetrate structures are formed in the winding substrate and configured as magnetically-permeable-core holes, each of the penetrate structures penetrating from the first side surface to the second side surface; parts of the winding substrate between the magnetically-permeable-core holes are configured as winding regions;
wherein the magnetically permeable core comprises at least three core legs and two core plates; the core plates are affixed to the first side surface or the second side surface respectively; the core legs are connected to the core plates through the selected magnetically-permeable-core holes;
wherein at least two windings are arranged in the winding substrate, the windings passing through the selected winding region or selected winding regions;
wherein one end of each of the windings is electrically connected with the selected AC terminal;
wherein another end of each of the windings is electrically connected with the selected DC terminal;
wherein the middle assembly is arranged between the upper assembly and the power pins;
wherein the first contact surface is configured to face the upper substrate; and
wherein the power semiconductor device is electrically connected with the selected AC terminals, and the output positive pins are electrically connected with the selected DC terminal or selected DC terminals.

Implementations of the power module may include one or more of following features. Further comprising a heat dissipation device arranged above the upper assembly;
wherein the heat dissipation device is in thermal connection with the power semiconductor device, and a lower surface of the heat dissipation device covers the upper substrate; an input power supply line is arranged in the heat dissipation device; and one end of the input power supply line is fixed and electrically connected with the upper substrate, and another end of the input power supply line extends out at a surface position of the heat dissipation device, and the surface position is not overlapped with the upper substrate.

Implementations of the power module may include one or more of following features. Further comprising one or more vertical boards; wherein the vertical board or each of the vertical boards is arranged in parallel to the middle assembly; the vertical board or at least one of the vertical boards comprises at least one conductive connector;
wherein the conductive connector is connected to the upper substrate through surface mount technology; and
wherein the ground pins are electrically connected with the upper assembly through the middle assembly or through the selected conductive connector or selected conductive connectors; and the input positive pins are electrically connected with the upper assembly through the middle assembly or through the selected conductive connector or selected conductive connectors.

Implementations of the power module may include one or more of following features. At least one counterbore is formed in the upper substrate, the conductive connector is connected to the upper substrate at the position of the selected counterbore; and
wherein at least one via conductive connector is configured in the upper substrate; the via conductive connector is electrically connected with a bottom of the selected counterbore; and the via conductive connector is electrically connected with the upper surface of the upper substrate.

Implementations of the power module may include one or more of following features. At least one throughbore is formed in the upper substrate, the conductive connector is connected to the upper substrate at the position of the selected throughbore.

Implementations of the power module may include one or more of following features. The middle assembly comprises at least two parallel winding substrates; the vertical board or at least one of the vertical boards is arranged between the winding substrates.

Implementations of the power module may include one or more of following features. The vertical board or at least one of the vertical boards comprises a controller and at least one low-voltage-high-frequency capacitor; wherein the low-voltage-high-frequency capacitor is electrically connected with the power semiconductor device; the low-voltage-high-frequency capacitor is configured as filter; and
wherein a groove-shaped structure is formed in an edge of the vertical board or at least one of the vertical boards, the low-voltage-high-frequency capacitor is located in the groove-shaped structure, and the low-voltage-high-frequency capacitor is electrically connected with the power semiconductor device; the low-voltage-high-frequency capacitor is configured as filter.

Implementations of the power module may include one or more of following features. A plurality of power semiconductor devices are provided; the power semiconductor devices include a high-voltage power semiconductor device and at least one low-voltage power semiconductor device, the upper assembly further comprises a high-voltage-high-frequency capacitor, and/or the upper assembly further comprises a low-voltage-high-frequency capacitor;
wherein the high-voltage power semiconductor device and the low-voltage semiconductor device are electrically connected with the selected AC terminals; and
wherein the high-voltage-high-frequency capacitor is electrically connected with the high-voltage power semiconductor device, and the high-voltage-high-frequency capacitor is configured to provide alternating current for the high-voltage power semiconductor device; the low-voltage-high-frequency capacitor is electrically connected with the high-voltage power semiconductor device, or the low-voltage-high-frequency capacitor is electrically connected with the low-voltage power semiconductor device; the low-voltage-high-frequency capacitor is configured as filter.

Implementations of the power module may include one or more of following features. Further comprising a lower substrate;
wherein the second contact surface is configured to face the lower substrate; the power pins are located on a surface of the lower substrate, and the output positive pins are electrically connected to the DC terminal through the lower substrate, the output positive pins and the ground pins are alternately arranged, and the input positive pins are arranged at an edge of the lower substrate; and
wherein at least one low-voltage-high-frequency capacitor is configured in the lower substrate; the low-voltage-high-frequency capacitor is electrically connected with the power semiconductor device; the low-voltage-high-frequency capacitor is configured as filter.

Implementations of the power module may include one or more of following features. Further comprising a lower substrate;
wherein the second contact surface is configured to face the lower substrate; the vertical board is electrically connected to the lower substrate through surface mount technology; and
wherein at least one counterbore or at least one throughbore is formed in the lower substrate, the conductive connector is connected to the lower substrate at the position of the selected counterbore or the selected throughbore.

Implementations of the power module may include one or more of following features. Further comprising a resonant inductor;
wherein the power semiconductor devices include a high-voltage power semiconductor device, the high-voltage power semiconductor device is electrically connected with the selected AC terminals through the resonant inductor.

Implementations of the power module may include one or more of following features. Further comprising at least one output inductor;
wherein the output inductor is arranged between the magnetically permeable core and the second contact surface; at least a part of the DC terminal is electrically connected with the output positive pin through the output inductor.

Implementations of the power module may include one or more of following features. The windings are in an even number and are arranged in pairs; the windings in each of the pairs respectively pass through the two winding regions separated by one of the core legs, and the windings in each of the pairs are connected to one selected DC terminal;
wherein the power semiconductor device or at least one of the power semiconductor devices comprises two switch groups electrically arranged in parallel; each switch group comprises two switch devices, at least one public source, a first drain and a second drain;
wherein the first drain and the second drain are configured for the electrically arranging in parallel; the windings in each of the pairs are respectively electrically connected with the first drain or the second drain in the selected switch group; and
wherein the switch groups are symmetrically arranged on the upper surface of the upper substrate by taking the position of the selected AC terminal as the center.

Implementations of the power module may include one or more of following features. Further comprising intermediate capacitors and post-stage buck circuit modules electrically connected with the selected DC terminal or selected DC terminals;
wherein each of post-stage buck circuit modules comprises one or more post-stage passive devices and one or more post-stage power semiconductors;
wherein the post-stage passive devices are arranged between the middle assembly and the lower substrate; the selected intermediate capacitors are arranged between the post-stage passive devices and the middle assembly, and/or the selected intermediate capacitors are arranged around the middle assembly; and
wherein the vertical board or at least one of the vertical boards is arranged aside an assembly of the post-stage passive devices, the intermediate capacitors and the middle assembly; the post-stage power semiconductors are configured on the vertical board.

In general, another aspect features encapsulation structure, comprising
two switch devices, a first drain pin, a second drain pin, a public source pin, and at least one signal pin;
wherein the public source pin is electrically connected to the source of either of the switch devices;
wherein the first drain pin is electrically connected with a drain of one of the switch devices, and the second drain pin is electrically connected with a drain of another of the switch devices; and
wherein the signal pins are arranged on one side of the encapsulation structure; the signal pins are configured for transmitting driving signals, and/or reporting current signals, and/or reporting temperature signals, and/or auxiliary power supply.
25. The encapsulation structure of claim 24, wherein the first drain pin and the second drain pin are arranged on two sides of the public source pin, and the signal pins are arranged aside an array of the first drain pin, the public source pin and the second drain pin.

Implementations of the encapsulation structure may include one or more of following features. The first drain pin and the second drain pin are arranged on one side of the public source pin, and the signal pins are arranged on another side of the public source pin.

Implementations of the encapsulation structure may include one or more of following features. Further comprising a printed circuit board;
wherein the switch device is embedded in the printed circuit board; the first drain pin, the second drain pin, the public source pin and the signal pins are arranged on a surface of the printed circuit board.

Implementations of the encapsulation structure may include one or more of following features. Encapsulation material is disposed on the switch devices; the first drain electrode pin, the second drain electrode pin, the public source pin and the signal pin are exposed out of the encapsulation material.

In general, another aspect features a system, comprising a system board, a chip, a power supply device, and at least one pair of input power supply lines;
wherein the input power supply lines include input positive wires and ground wires;
wherein the chip is installed on the surface of one side of the system board; signal pins and power supply pins are configured on a surface of the chip; the signal pins are arranged around the power supply pins; the power supply pins include power supply positive pins and power supply negative pins;
wherein the power supply device is installed opposite to the chip on the surface of another side of the system board; the power supply device is configured to provide direct current for the chip across the system board through vias; and
wherein the input power supply lines are configured to cross over a signal-via region of the system board; the input power supply lines are configured to provide power supply for the power supply device.

Implementations of the system may include one or more of following features. One end of each of the input power supply lines is connected to the system board or a connector on the system board at a position out of the signal-via region.

Implementations of the system may include one or more of following features. Another end of each of the input power supply lines is connected to the system board or a connector on the system board at a position between the signal-via region and power supply device.

Implementations of the system may include one or more of following features. Another end of each of the input power supply lines is connected to the upper surface of the power supply device.

Implementations of the system may include one or more of following features. Further comprising a heat dissipation device arranged on the power supply device;
wherein the heat dissipation device is in thermal connection with the upper surface of the power supply device, and the input power supply lines penetrate through the heat dissipation device.

Implementations of the system may include one or more of following features. The input power supply lines are configured to provide a voltage greater than or equal to 30V. The details of one or more embodiments of the invention are set forth in the accompanying drawings and description below. Other features, objects, and advantages of the invention will be apparent from the description and drawings, and from the claims.

### DESCRIPTION OF DRAWINGS

FIGS. 1A to 1C are three-dimensional views and exploded three-dimensional views of power modules according to some embodiments;

FIG. 1D is a schematic diagram of the circuit topologies according to one or more embodiments;

FIG. 1E is an exploded three-dimensional view of the magnetic apparatuses according to one or more embodiments;

FIG. 1F is a schematic diagram of the winding according to one or more embodiments;

FIGS. 1G to 1I are schematic diagrams of partial structures of the magnetic apparatuses according to one or more embodiments;

FIGS. 2A and 2B are three-dimensional views of magnetic apparatuses according to one or more embodiments;

FIG. 3A is a schematic diagram of the winding in an exploded side view according to one or more embodiments;

FIGS. 3B and 3C are schematic diagrams of the terminal arrangements according to one or more embodiments;

FIG. 3D is a pin-layout diagram according to one or more embodiments;

FIG. 3E is a pin-arrangement diagram according to one or more embodiments;

FIGS. 4A and 4B are schematic diagrams of the magnetic apparatuses according to one or more embodiments;

FIGS. 5A to 5F are schematic diagrams of the power modules according to one or more embodiments;

FIGS. 6A and 6B are schematic diagrams of the power supply system according to one or more embodiments;

FIGS. 7A is a schematic diagram of the circuit topologies of the power modules according to one or more embodiments;

FIGS. 7B and 7C are side views of the power modules in general according to one or more embodiments;

FIGS. 8A and 8B are schematic diagrams of the power modules showing details of the layout of high-voltage-high-frequency capacitors or low-voltage-high-frequency capacitors according to one or more embodiments;

FIG. 9 is a schematic diagram of the power module for buck circuit according to one or more embodiments;

FIGS. 10A to 10E are pin layout schematic diagrams of the multiple-switch encapsulations according to one or more embodiments.

### DETAILED DESCRIPTION

The present application discloses various embodiments or examples of implementing the thematic technological schemes mentioned. To simplify the disclosure, specific instances of each element and arrangement are described below. However, these are merely examples and do not limit the scope of protection of this invention. For instance, a first feature recorded subsequently in the specification formed above or on top of a second feature may include an embodiment where the first and second features are formed through direct contact, or it may include an embodiment where additional features are formed between the first and second features, allowing the first and second features not to be directly connected. Additionally, these disclosures may repeat reference numerals and/or letters in different examples. This repetition is for brevity and clarity and does not imply a relationship between the discussed embodiments and/or structures. Furthermore, when a first element is described as being connected or combined with a second element, this includes embodiments where the first and second elements are directly connected or combined with each other, as well as embodiments where one or more intervening elements are introduced to indirectly connect or combine the first and second elements.

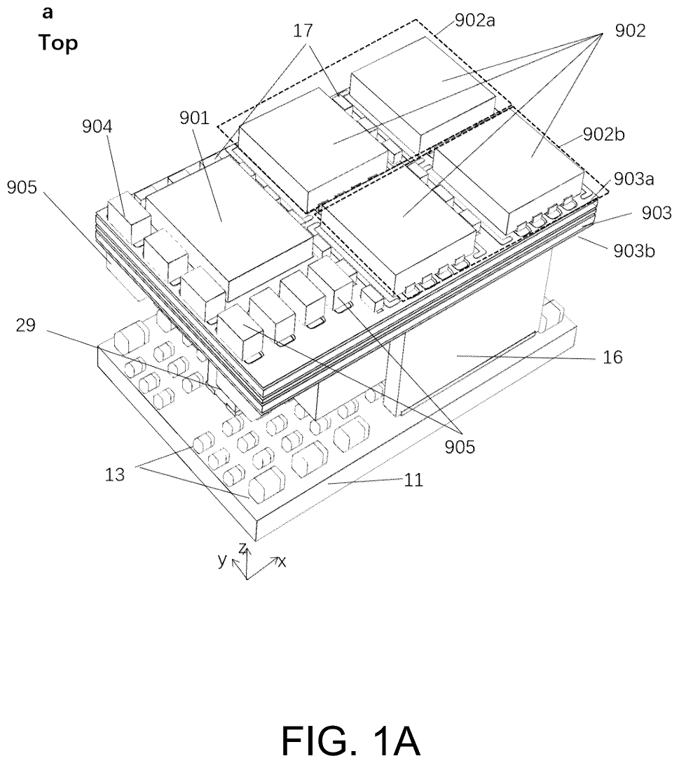

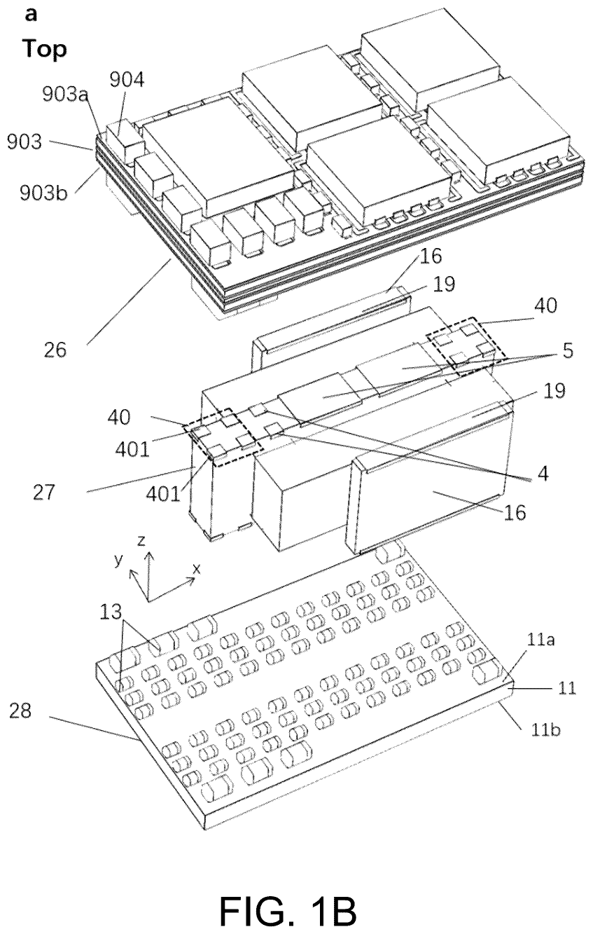

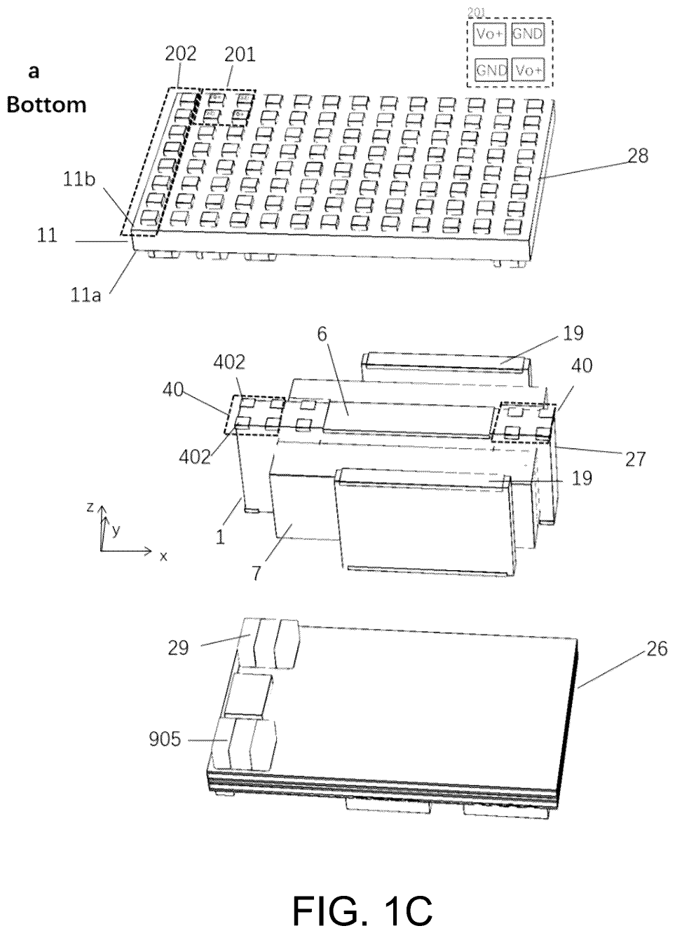

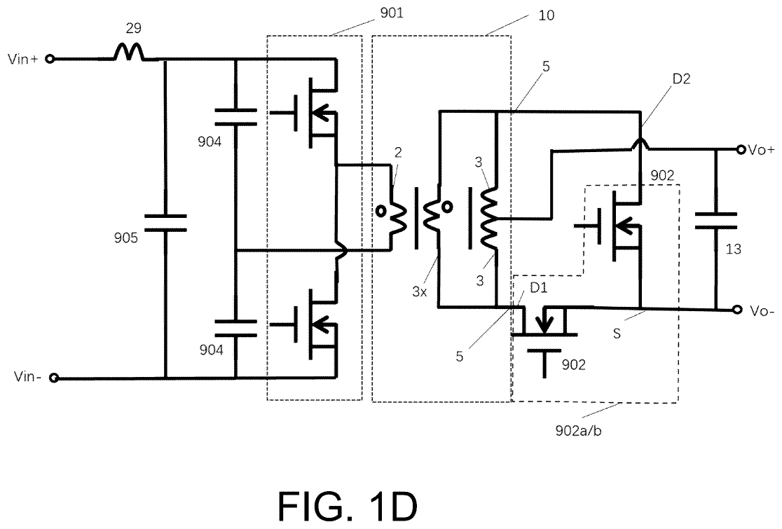

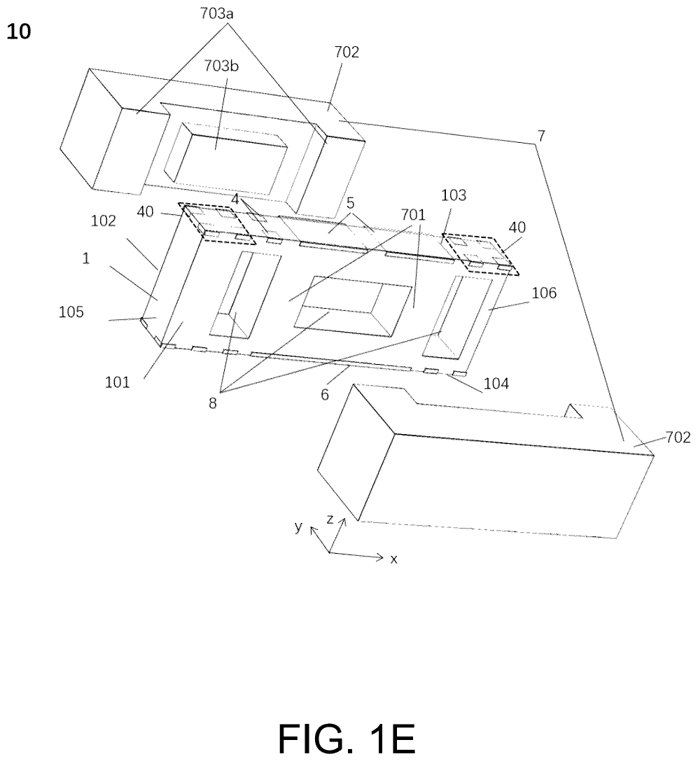

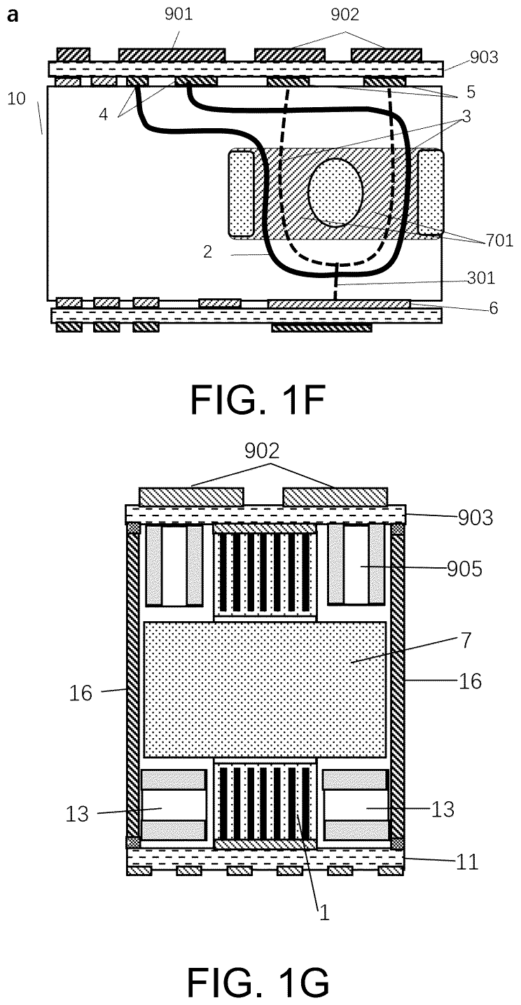

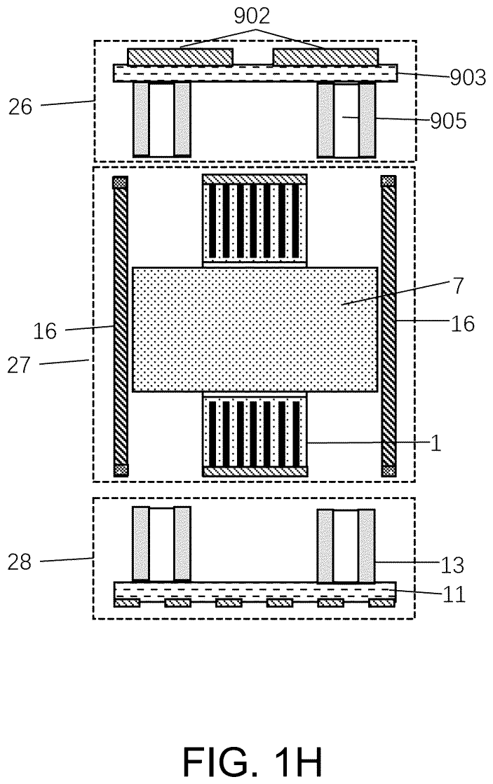

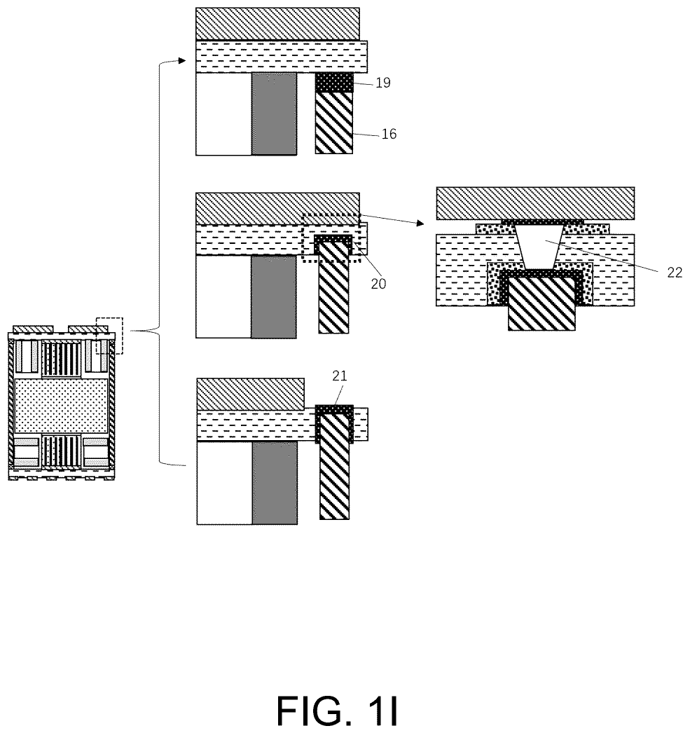

FIGS. 1A to 1D show the structure of the magnetic apparatuses in one or more embodiments. FIG. 1A is a three-dimensional view of the power module A, FIG. 1B is an exploded view (from the top) of the power module A, and FIG. 1C is another exploded view (from the bottom) of the power module A. FIG. 1D is a schematic diagram of the circuit topology selected to the power module A.

Referring to FIG. 1A to FIG. 1D, the power module A includes an upper assembly 26, a second assembly 27 and a lower assembly 28, and the upper assembly 26 and the lower assembly 28 are respectively arranged on two opposite sides of the second assembly 27. The upper assembly 26 comprises an upper substrate 903. The upper substrate 903 is provided a first surface 903a (i.e., the upper surface in FIG. 1B) and a second surface 903b which are opposite to each other. Multiple semiconductor devices and multiple capacitors are arranged on the first surface 903a. Referring to FIG. 1D, the semiconductor devices include a high-voltage power semiconductor device 901; a switch bridge arm formed by connecting two switches in series and a driving unit of the switch bridge arm are integrated in the high-voltage power semiconductor device 901. In some embodiment, in addition, the high-voltage power semiconductor device 901 also comprises current detection units and temperature detection units of the switches. Multiple capacitors include a plurality of high-voltage-high-frequency capacitors 904, high-voltage-high-frequency capacitors 904 are electrically connected to form capacitor bridge arms, and the capacitor bridge arms and the switch bridge arms are electrically connected in parallel respectively; multiple capacitors further include at least one input capacitor 905 which is arranged on the second surface 903b or the first surface 903a, and is arranged adjacent to the high-voltage power semiconductor device 901 together with the capacitor bridge arm, and provides alternating current for the high-voltage power semiconductor device 901, so that the parasitic inductance of a loop formed by multiple capacitors and the switch bridge arm is minimized, and the power loss of the high-voltage power semiconductor device 901 is reduced;

Multiple semiconductor devices further include a plurality of low-voltage power semiconductor devices 902 equally divided into two groups 902a and 902b; devices within the group 902a are arranged in an array along the x-axis direction, and devices within the group 902b are arranged in another array along the x-axis direction, as shown in FIG. 1A. Each of the groups 902a and 902b includes two low-voltage power semiconductor devices 902. Referring to FIG. 1D, in some embodiment, low-voltage power semiconductor devices are MOSFETs; the sources of the two low-voltage power semiconductor devices 902 in one group are shorted to form a public source S, one drain D1 is electrically connected with a low-voltage AC terminal 5, and another drain D2 is electrically connected with another low-voltage AC terminal 5. The drain D1, the public source S and the drain D2 of the group 902a are in one-to-one correspondence short-circuited with the drain D2, the public source S and the drain D1 of the group 902b, so that groups 902a and 902b are configured in diagonal symmetry. The symmetric arrangement is used for improving the output loading capacity of the power module, reducing the loss of the power supply module and improving the conversion efficiency. In the embodiment shown in FIG. 1A, the power module A further comprises a set of auxiliary power supply capacitors 17 which are adjacent to the high-voltage power semiconductor device 901 and/or the low-voltage power semiconductor device 902 and are used for providing filtering for auxiliary power supply to multiple semiconductor devices. The high-voltage power semiconductor device 901 and multiple capacitors are arranged on one side (i.e., a high-voltage region) of the upper substrate 903, and the low-voltage power semiconductor devices 902 are arranged on the other side (i.e., a low-voltage region) of the upper substrate 903. In addition, the heights of the high-voltage-high-frequency capacitors 904 and at least one input capacitor 905 are less than 1 mm, so that the semiconductor devices are the higher or the highest devices on the first surface 903a. Therefore the semiconductor devices is nearer or the nearest to the external cooling fins; the thermal resistance between the semiconductor device and the external cooling fins is minimized. Compared with the capacitors, the semiconductor devices are configured to have a better heat dissipation, and the reliability of the power module is greatly improved. In some embodiment, at one side of the high-voltage region, devices with relatively higher height are placed, such as some of the input capacitors 905 and input filter inductors 29 with relatively higher heights. They form an open region that the external cooling fins do not cover.

The lower assembly shown in FIGS. 1A to 1C comprises a lower substrate 11 (i.e., a pin conversion plate), multiple pins and multiple low-voltage-high-frequency capacitors 13, wherein the lower substrate 11 is provided with a third surface 11a and a fourth surface 11b. The pins are arranged on the fourth surface 11b. The pins include power pins and signal pins, and the power pins include input positive pins Vin+, output positive pins Vo+ and ground pins GND. In some embodiment, input negative pins Vin− and output negative pins Vo− (as shown in FIG. 1D) are both configured as ground pins GND, that is, the input negative pins Vin− and the output negative pins Vo− are short-circuited. The output positive pins Vo+ and the ground pins GND are alternatively arranged (as the arrangement in a region 201 shown in FIG. 1C); the parasitic inductance on the large-current circuit path is thus divided into portions and reduced, so that the dynamic performance of the power module A is improved. Input positive pins Vin+ and signal pins are arranged in a region 202; the signal pins are configured for transmitting control signals and auxiliary power supply signals to the power module A, and transmitting current sampling signals and temperature sampling signals from the power module A.

As shown in FIG. 1B, FIG. 1C and FIG. 1E, the second assembly 27 comprises a magnetic apparatus 10 (i.e., a middle assembly) and two vertical boards 16, a first contact surface 103 of the magnetic apparatus 10 is configured to face the upper assembly 26, the second contact surface 104 is configured to face the lower assembly 28, and the two vertical boards 16 are respectively arranged on two opposite sides of the magnetic apparatus 10; the magnetic apparatus 10 further comprises a magnetically permeable core 7 and a winding substrate 1; the magnetically permeable core 7 comprises two core plates 702. In some embodiment, parts of the core legs 703 are integrally formed with one of the core plates 702 and other parts of the core legs 703 are integrally formed with the other of the core plates 702. The structure of the magnetically permeable core 7 is not limited thereto. In other embodiments, all of the core legs 703 are integrally formed with one of the core plates 702, or selected one(s) of the core legs 703 are integrally formed with the selected one of the core plates 702, or the core legs 703 and the core plates 702 are individually manufactured and then assembled. In some embodiment, the core legs 703 include two side core legs 703a and one middle core legs 703b, and the middle core legs 703b is disposed between the two side core legs 703a.

As shown in FIG. 1E, the winding substrate 1 is provided with a first side surface 101 and a second side surface 102 opposite to each other. A first contact surface 103 and a second contact surface 104 are configured on opposite directions of the winding substrate 1 between the first side surface 101 and the second side surface 102. The X-axis direction shown in the FIG. 1E is the length direction of the winding substrate, the Y-axis direction is the thickness direction, and the Z-axis direction is the height direction. At least three penetrate structures are formed in the winding substrate and are configured as magnetically-permeable-core holes 8, each of the penetrate structures penetrating from the first side surface 101 to the second side surface 102, with each of the core legs 703 passing through a corresponding magnetically-permeable-core holes 8. The penetrate structure formed in the edge of winding substrate is in a groove-like shape, and the one formed in the middle is in a hole-like shape. Multiple magnetically-permeable-core holes 8 are sequentially arranged in the X-axis direction shown in the FIG. 1E. The shapes and the sizes of the magnetically-permeable-core holes 8 are not limited, and the magnetically-permeable-core holes 8 can be configured according to the shapes and sizes of the core legs in some embodiment. The regions between the magnetically-permeable-core holes 8 is configured as winding regions 701. Two high-voltage AC terminals 4 and two low-voltage AC terminals 5 are arranged on the first contact surface 103, and a DC terminal 6 is arranged on the second contact surface 104; the DC terminal is used for providing direct-current output. In addition, the winding substrate 1 is further provided with electric connection regions 40. In some embodiment, as shown in FIG. 1B, along the X-axis direction on the first contact surface 103, one of the electric connection regions 40, the high-voltage AC terminals 4, the low-voltage AC terminals 5 and another of the electric connection regions 40 are sequentially arranged; and on the second contact surface 104, as shown in FIG. 1C, one of the electric connection regions 40, one low-voltage DC terminal 6 and another of the electric connection regions 40 are sequentially arranged. The arrangement of the terminals/regions is not limited thereto. In other embodiments, the arrangement can be carried out according to actual requirements.

Referring to FIG. 1F, a high-voltage winding 2 and two low-voltage windings 3 are configured in the winding substrate 1, either of the low-voltage windings 3 passing through the corresponding one of two winding regions 701 separated by one core leg 703 (which is the middle core leg 703b referring to FIG. 1E), and one end of either of the low-voltage windings 3 is electrically connected to a corresponding low-voltage AC terminal 5 on the first contact surface 103, i.e., a low-voltage AC terminal 5 as shown in FIG. 1D, and is electrically connected to the drain electrode of the corresponding low-voltage power semiconductor device 902 through the upper substrate 903. The other ends of the low-voltage windings 3 are short-circuited, with the public extension line 301 electrically connected with the corresponding DC terminal 6 on the second contact surface 104. The DC terminal 6 is electrically connected with the output positive pin Vo+ through the lower substrate 11. The high-voltage winding 2 passes through multiple winding regions 701 and is coupled with either of the low-voltage windings 3 (in some embodiment, the low-voltage windings 3 are arranged in pairs, the electromotive force directions generated by coupling are opposite), two ends of the high-voltage winding 2 are electrically connected respectively with the two high-voltage AC terminals 4, one of which is electrically connected with the midpoint of the switch bridge arm in the high-voltage power semiconductor device 901 and the other is electrically connected with the midpoint of the capacitor bridge arm through the upper substrate 903. The two vertical boards 16 are arranged on the two sides of the magnetic apparatus 10 respectively and are perpendicular to the upper substrate 903 and the lower substrate 11. The vertical boards 16 are used for supporting and electromagnetic isolating, and are in addition used for electric connection with connector terminals 19 shown in FIGS. 1B and 1C electrically connected with the upper substrate 903 or the lower substrate 11. Through the vertical boards 16, the ground pins GND of the lower assembly 28 are electrically connected with the public source S of the low-voltage power semiconductor devices 902 in the upper substrate 903.

Referring to FIG. 1D, one of the high-voltage AC terminals 4 is electrically connected with the high voltage power semiconductor device 901 (i.e., to the midpoint of the switch bridge arm), and another is electrically connected to the midpoint of the capacitor bridge arm. AC voltage between the midpoint of the switch bridge arm and the midpoint of the capacitor bridge arm determines the voltage between two high-voltage AC terminals 4 of the winding substrate 1, so that the high-voltage winding 2 is driven by the AC voltage. The two low-voltage windings 3 are not only configured as two output inductors which are connected in series, but also equivalently as a transformer secondary winding 3x which is connected in parallel with the two output inductors. The two ends of the transformer secondary winding 3x are electrically connected with the two low-voltage AC terminals 5 respectively, and the transformer secondary winding 3x is magnetically coupled with the high-voltage winding 2 (which is configured as a transformer primary winding) to form a equivalent transformer. The terminal of the high-voltage winding 2 connected with the midpoint of the half-bridge arm is configured as one of the dotted ends, and the dotted end of the transformer secondary winding 3x is determined by the direction of the magnetic coupling, as shown in FIG. 1D. The sources of the low-voltage power semiconductor devices 902 are electrically connected with each other, and the drain electrodes of the low-voltage power semiconductor devices 902 are electrically connected with the two low-voltage AC terminals 5. The low-voltage-high-frequency capacitor 13 is bridged between the connection point of the two low-voltage windings 3 (which is electrically connected with the output positive pins Vo+) and the public source S of the low-voltage power semiconductor devices 902 (which is electrically connected with a terminal Vo− in FIG. 1D, the terminal Vo− is configured to be ground pins GND in the power module A). When the dotted end of the high-voltage winding 2 has a positive voltage relative to the non-dotted end of the high-voltage winding 2, the dotted end of the transformer secondary winding 3x is also coupled with a positive voltage relative to the non-dotted end, and the low-voltage power semiconductor device 902 connected with the non-dotted end is configured to turn on at the same time, so that the low-voltage winding 3 connected with the dotted end is configured to provide the output voltage. When the dotted end of the high-voltage winding 2 has a negative voltage relative to the non-dotted end of the high-voltage winding 2, the dotted end of the transformer secondary winding 3x is also coupled with a negative voltage relative to the non-dotted end, and the low-voltage power semiconductor connected with the dotted end is configured to turn on at the same time, so that the low-voltage winding 3 connected with the non-dotted end is configured to provide the output voltage. When the two ends of the high-voltage winding 2 have relatively a zero voltage, the two ends of the transformer secondary winding 3x are also coupled with zero voltage, and both of the low-voltage power semiconductors 902 are configured to turn on, so that the two low-voltage windings 3 are configured to provide the output voltage respectively. According to the aforementioned configurations and principle, the low-voltage windings 3, the low-voltage power semiconductors 902 and the low-voltage-high-frequency capacitors 13 form a current-multiplying rectifier circuit. In other embodiments, the capacitor bridge arm is replaced by another switch bridge arm to form a full-bridge circuit, and the configurations and the basic principle of the full-bridge circuit are similar to those of the half-bridge circuit (i.e., the aforementioned configurations and principle). In other embodiments, the high-voltage winding 2 passes through the same winding region 701 multiple times, that is, the high-voltage winding 2 forms a multiple-turn winding around the middle core leg 703b.

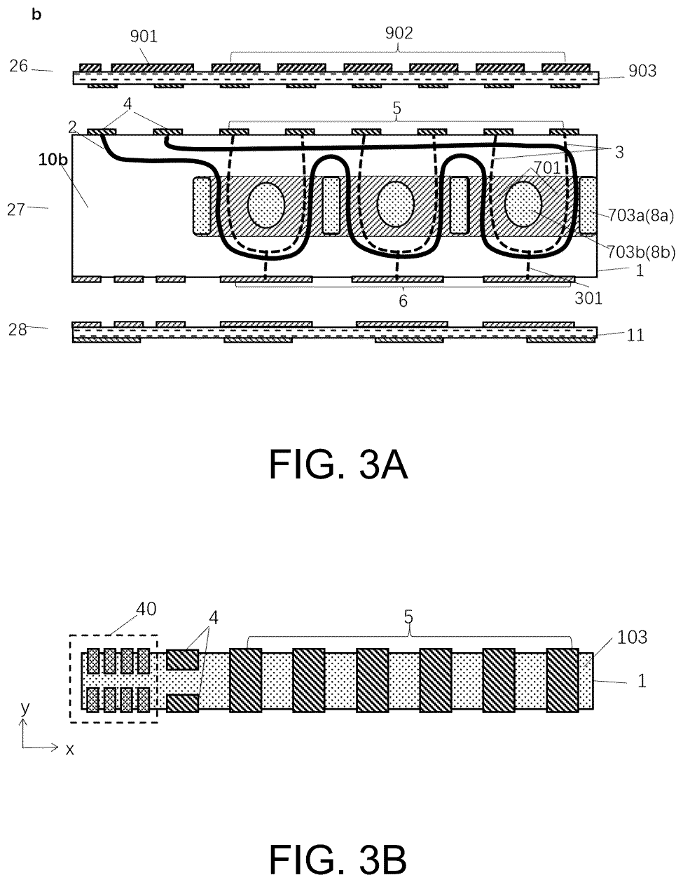

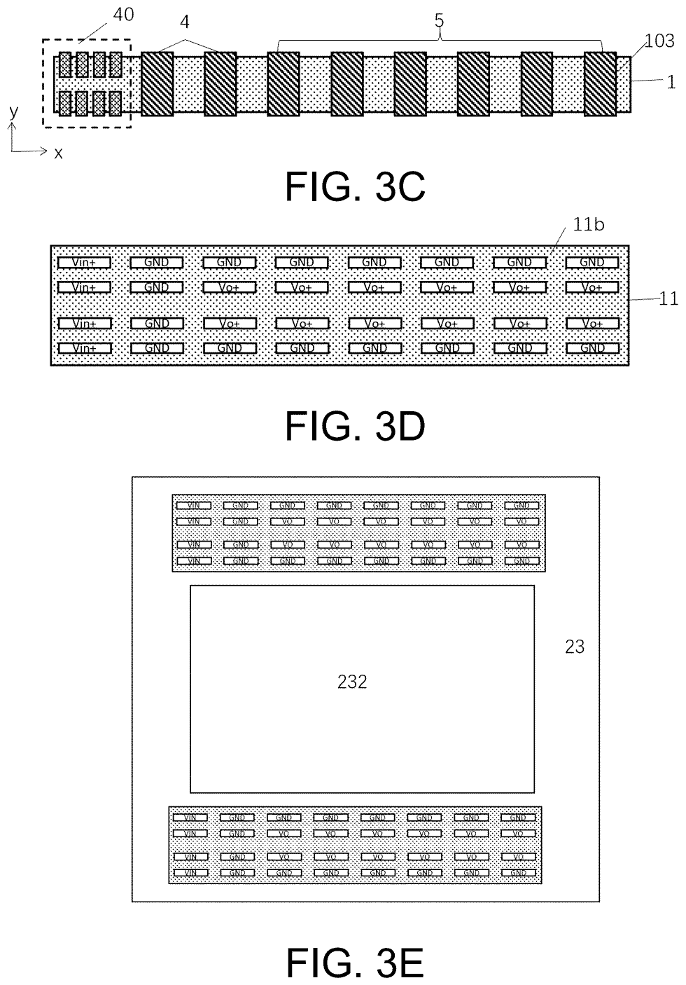

The winding substrate 1 may be provided with electric connection regions 40 for transmitting control signals and auxiliary power supply signals from the lower substrate 11 to the upper assembly 26 for the semiconductor devices disposed on the first surface 903a, and transmitting current sampling signals and temperature sampling signals from the upper assembly 26 to the lower substrate 11. The electric connection regions 40 comprises first additional terminals 401 located on the first contact surface 103, second additional terminals 402 located on the second contact surface 104, and additional conductive connectors electrically connected with the first additional terminals 401 and the corresponding second additional terminals 402. Due to the fact that the current passing through the electric connection region is usually low, in order to minimize the occupied area of the terminals, the additional terminals can be arranged in pairs (referring to FIG. 3B. and FIG. 3C). In some embodiment, two first additional terminals 401 and two second additional terminals 402 are taken as examples: A first additional terminal 401 and a corresponding second additional terminal 402 are arranged adjacent to the first side face 101 and are electrically connected with a conductive connector arranged on or in the winding substrate 1; and correspondingly, the other first additional terminal 401 and the other second additional terminal 402 are arranged at the opposite side. In some embodiment, some of the additional terminals are configured as input positive terminals Vin+: the input power voltage is transmitted from the lower substrate 11, through the electrical connection region 40, to the upper assembly 26, and to the input filter inductor 29 and the input capacitor 905 in detail. Signals on the lower substrate 11, including PWM signal, current sampling signals, temperature sampling signals, and auxiliary power supply signals for the high-voltage power semiconductor device and the low-voltage power semiconductor devices, are transmitted between the upper assembly 26 and the lower substrate 11 through the first additional terminals 401, conductive connectors, and the second additional terminals 402 in pairs, so that the winding substrate 1 is provided with multiple functions of not only conversing and transmitting electric power from the input to the output, but also integrating signal connection functions.

In some embodiment, the middle core legs 703b of the magnetically permeable core 7 is provided with a low-magnetic-resistance design, so that the current ripple flowing through the high-voltage winding and the current ripple of the low-voltage windings are minimized, while the side core legs 703a are provided with a high-magnetic-resistance design, so that magnetic flux saturation of each of the low-voltage windings is not generated. In some embodiments, the high-voltage AC terminal 4 and the low-voltage AC terminal 5 are both located on the first contact surface 103 of the winding substrate 1, and the DC terminal 6, as a connection point of the two low- voltage windings 3 in FIG. 1D, is located on the second contact surface 104. On one hand, the high-voltage power semiconductor device 901 and the low-voltage power semiconductor devices 902 which are respectively electrically connected with the high-voltage winding 2 and the low-voltage winding 3 can be completely integrated in another assembly on one side of the magnetic apparatus, so that the power semiconductor devices are exposed outwards for an easier installment of a heat dissipation device, wherein the heat dissipation path between the power semiconductor devices and the heat dissipation device is short, and the thermal resistance is low. On another hand, the low-voltage winding 3 directly pass through the winding region and is connected with the DC terminal 6, so that the path lengths of the low-voltage windings are minimized, the parasitic resistance on the low-voltage windings is minimized, the power loss is minimized, and the current density of the magnetic apparatus is improved. In some embodiment, in addition, the low-voltage windings 3 are arranged on multiple layers in the winding substrate 1, and the parallel electric connection of the low-voltage windings in multiple layers is configured through vias in throughbores or blind holes or half holes in the substrate or through electroplating on the edge of the layers, so that a high-voltage low-current power input is converted to a low-voltage high-current power output, and the loading capacity of the low-voltage high current is improved.

The input positive pin Vin+ of the power module A is electrically connected with a DC power supply terminal in the electric connection region 40 on the winding substrate 1 through the lower substrate 11, and the signal pins of the power module A are electrically connected with signal terminals in the electric connection region 40 on the winding substrate 1 through the lower substrate 11. Referring to the circuit topology shown in FIG. 1D, some of the low-voltage-high-frequency capacitors 13 are arranged on the third surface 11a. Some of the low-voltage-high-frequency capacitors 13 with a relatively higher height are placed at a wide side space on the third surface 11a corresponding to the high-voltage region of the upper substrate 903, thereby obtaining a sufficiently large output capacitance value; some of the low-voltage-high-frequency capacitors 13 with a relatively lower height are placed at a gap between the third surface 11a of the lower substrate 11 and the magnetically permeable core 7, so that the parasitic inductance between each pin on the lower substrate and the output capacitor is minimized, and the influence of the parasitic inductance on the dynamic performance of the power module is reduced.

The output positive pins Vo+ and the ground pins GND are alternatively arranged. In some embodiment, the pins are arranged in one-to-one correspondence with the pins of a large intelligent IC of a client mainboard, including the power supply positive pins and the power supply negative pins which are also alternatively arranged, with the same distances between pins, and the positions of the pins are vertically aligned at the installment. The output positive pins Vo+ of the power module A and the large intelligent IC power supply positive pins are electrically connected through respective vias. The ground pins GND of the power module A and the large intelligent IC power supply negative pins are electrically connected through respective vias. In this way, the parasitic resistance from the output pins of the power module A to the power supply pins of the large intelligent IC is reduced, so that the current transmission loss is reduced. Secondly, the parasitic inductance between the output pins of the power module A and the power supply pins of the large intelligent IC is reduced, so that when the current consumption of the power input of the large intelligent IC changes dynamically, the voltage fluctuation range between the power supply positive pins and the power supply negative pins of the large intelligent IC is reduced.

In some embodiment, one of the vertical boards 16 integrates the controller of the power module A, and low-voltage-high-frequency capacitors 13 are placed on the vertical board 16, as shown in FIG. 1G, so that the output current ripples are further reduced, and the dynamic response performance of the power module A is improved. In some embodiment, the power module A includes only one vertical board 16 adjacent to one side of the magnetic apparatus 10 and disposed in parallel with the winding substrate 1.

The winding substrate 1 is vertically arranged in the power module A, that is, the first contact surface 103 is in contact with and electrically connected to the second surface 903b of the upper substrate 903, and after the winding substrate 1 and the upper substrate 903 are assembled, the low-voltage power semiconductor device groups 902a and 902b are respectively arranged on two sides of the winding substrate 1 and approximately satisfy diagonal symmetry. The drain D1 in the group 902a and the drain D2 in the group 902b are symmetrically distributed over both sides of the winding substrate 1 on the upper substrate 903, and are electrically connected to one low-voltage AC terminal 5 at the shortest wiring; the drains D2 in the group 902a and the drain D1 in the group 902b are symmetrically distributed over both sides of the winding substrate 1 on the upper substrate 903, and are electrically connected to another one low-voltage AC terminal 5 through the shortest wiring; and the sources of the low-voltage power semiconductor device groups 902a and 902b are short-circuited through the shortest wiring. By means of the connection, the alternating current loop formed by the two low-voltage windings 3 and the two low-voltage power semiconductor groups 902a and 902b is minimized, and the coupling between the two low-voltage windings 3 and the high-voltage winding 2 is optimized, so that the leakage inductance of the magnetic part is minimized, and the high-frequency switching loss of the high-voltage power semiconductor device and the low-voltage power semiconductor devices is also minimized. The paving copper of the two short-circuited sources is connected with the ground pins GND on the vertical boards 16 on the two sides of the magnetic apparatus 10, so that the source current flows through the shortest distance to the ground pin GND, and the vertical boards 16 are configured to provide the shortest wiring path between the short-circuited sources and the ground pin GND of the lower substrate 11, so that the parasitic resistance on the wiring is reduced, and the conduction loss of the power module A is reduced. The configuration of the pins and the connections is not limited thereto.

FIG. 1G is a side view of the power module A, FIG. 1H is a side view explosion diagram of the power module A, and FIG. 1I is a side view local diagram of the power module A. Referring to FIG. 1G to 1H, the second assembly 27 is disposed between the upper assembly 26 and the lower assembly 28, and the winding substrate 1 and the vertical board 16 are respectively in contact with and electrically connected to the upper substrate 903 and the lower substrate 11. Part of the high-voltage-high-frequency capacitor 905 is arranged on the second surface 903b of the upper substrate 903 and located between the vertical board 16 and the winding substrate 1, more input capacitors 905 are arranged through gaps between the vertical board 16 and the winding substrate 1, input voltage ripples are further reduced, and high-power density and small size of the power module A are achieved Similarly, the low-voltage-high-frequency capacitor 13 can also be arranged in a gap between the vertical board 16 and the winding substrate 1. In one embodiment, as shown in FIG. 1G, the low-voltage-high-frequency capacitor 13 can be arranged on the vertical board 16; in another embodiment, as shown in FIG. 1H, the low-voltage-high-frequency capacitor 13 is arranged on the lower substrate 11.

In one or more embodiments, as shown in FIG. 1I (only the connection portion of the vertical board 16 and the upper assembly 26), electric connection terminals (including a high-voltage AC terminal 4, a low-voltage AC terminal 5 and an electric connection region 40 disposed in the first contact surface 103, a DC terminal 6 disposed on the second contact surface 104, and a port in the electric connection region 40, and an electric connection terminal 19 disposed on the vertical plate 16) are surface-mounted pins (SMD). One of the upper assembly 26 or the lower assembly 28 is welded as a whole and then welded to another assembly. In this way, the requirement for the assembly process of the second assembly 27 is high, and there is an extremely high flatness between the electric connection port on the first contact surface 103 of the winding substrate 1 and the electric connection terminal 19 on one side of the vertical board 16; or there is an extremely high flatness between the electric connection port on the second contact surface 104 of the winding substrate 1 and the electric connection terminal 19 on the other side of the vertical board 16.

In some embodiments, the vertical board 16 can be directly inserted and welded through the throughbore 21 or the counterbore 20 in the upper assembly 26 and the lower assembly 28, respectively. An electroplating pit slot is formed in the counterbore 20, and the depth of the electroplating pit slot is about half of the thickness of the upper substrate 903. A via conductive member 22 is further arranged at the bottom of the counterbore 20 and is used for electrically connecting the counterbore 20 and the bonding pad on the first surface 903a of the upper substrate 903. The throughbore and the counterbore can solve the problem that the electric connection terminals on the first contact surface 103 of the winding substrate 1 and the electric connection terminal 19 on one side of the vertical board 16 are not on the same horizontal plane, or the electric connection terminals on the second contact surface 104 of the winding substrate 1 and the electric connection terminal 19 on the other side of the vertical board 16 are on the same horizontal plane, because the design can enable the part of the electric connection port on the protruding winding substrate 1 of the electric connection terminal 19 on the vertical board 16 to be located in the throughbore or the counterbore. In addition, the ground pin GND in the lower substrate 11 and the public source S of multiple low-voltage power semiconductor devices 902 can be connected to the shortest distance through the vertical board, so that the shortest current path is realized. The region of GND wiring is reduced, and the electrical conduction loss on the GND wiring path is reduced.

In some embodiments, all the electric connection ports on one side of the second assembly 27 are surface mounting pins (SMD), and the electric connection terminals of the other side and the magnetic apparatus 10 are surface mounting pins (SMD), but the electric connection ports of the vertical boards 16 are directly inserted into the throughbore or the counterbore for welding. In the assembling step, all electric connection ports of the second assembly 27 need to be welded at first, and then welding on the other side of the second assembly 27 is completed. Due to the fact that the vertical board 16 on the other side is welded and fixed through the throughbore 21 or the counterbore 20, the requirement for the flatness between the electric connection ports of the second assembly 27 can be effectively reduced, the assembly difficulty of the second assembly 27 is reduced, and production can be achieved.

As shown in FIG. 1H, a method of making the power module of some aforementioned embodiment comprises step 1 to step 3:

In the step 1, the upper assembly 26 is assembled, the upper assembly comprises an upper substrate 903, a part of the input capacitor 905 is mounted on the second surface of the upper substrate 903, and the contour shape after mounting the input capacitor 905 matches the shape of the magnetic apparatus 10; a second assembly 27 is assembled, wherein the a second assembly 27 comprises a magnetic apparatus 10 (i.e., middle assembly) and two vertical boards 16, and the magnetic apparatus 10 and the vertical boards 16 are fixedly connected through bonding; and a lower assembly 28 is assembled, the lower assembly 28 comprises a lower substrate 11, and the low-voltage-high-frequency capacitors 13 are arranged on the lower substrate 11; one of the upper assembly 26 and the lower assembly 28 is configured as a first assembly which is firstly welded to the second assembly 27 in step 2, and the other is configured as a third assembly which is welded to the second assembly 27 in step 3; throughbores 21 and/or counterbores 20 are configured in the third assembly for the welding (as shown in FIG. 1I);

In the step 2, the first assembly and the second assembly 27 are welded together;

In the step 3, the third assembly and the second assembly are welded together.

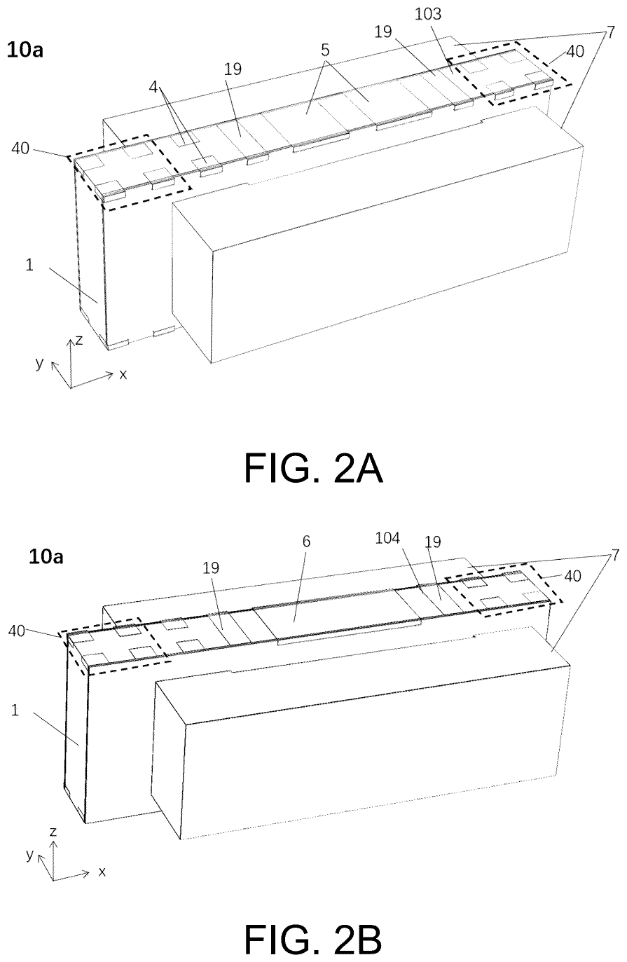

In some embodiments, the second assembly 27 may not include a vertical board, including only one magnetic apparatus 10a, as shown in FIGS. 2A and 2B, disposed between the upper assembly 26 and the lower assembly 28, which is not described herein again. The electric connection terminal 19 provided on the first contact surface 103 is electrically connected to the electric connection terminal 19 provided on the second contact surface 104 by means of the wiring or conductor on the winding substrate 1. In the present embodiment, the electric connection terminal 19 is the ground terminal GND. The vertical board is removed, and the electric connecting terminal 19 is moved to the winding substrate 1, so that the production process can be further simplified, and the size of the power module is further reduced. In the present embodiment, the optimal arrangement of the electric connection ports provided on the first contact surface 103 is, along the X-axis direction shown in FIG. 2A, on the first contact surface 103, the electric connection region 40, the high-voltage AC terminal 4, the electric connection terminal 19 (GND), the low-voltage AC terminal 5, the electric connection terminal 19 (GND) and the electric connection region 40 are arranged in sequence; on the second contact surface 104, the electric connection region 40, the electric connection terminal 19 (GND), the low-voltage DC terminal 6, the electric connection terminal 19 (GND) and the electric connection region 40 are sequentially arranged. The arrangement of the electric connection ports is not limited thereto, and can be designed according to a winding method and the like.

In one or more embodiments, the magnetic apparatus and even the whole power module Can be expanded and set according to power requirements. Referring to the magnetic piece module schematic diagram shown in FIG. 1F, in combination with the side view schematic diagram of the power module B shown in FIG. 3A, the structure of the power module B, the magnetically permeable core structure of the magnetic apparatus 10b, the high-voltage winding 2 and the winding method of multiple low-voltage windings 3 are disclosed. The middle core legs 703b can be expanded to two, three or more, here, the magnetic apparatus 10b is expanded to three for description by taking the number of the middle core legs 703b. With reference to the side face perspective schematic diagram shown in FIG. 3a, the winding substrate 1 comprises three magnetically-permeable-core hole 8b corresponding to the middle core legs 703b; the number of the side core legs 703a is four, four magnetically-permeable-core hole 8a corresponding to the side core legs 703a are correspondingly arranged on the winding substrate 1, the seven hole grooves define six winding regions 701, the number of the low-voltage AC terminals 5 arranged on the first contact surface 103 of the winding substrate 1 is expanded to 6, and the number of the high-voltage AC terminals 4 is still two; the number of the DC terminals 6 arranged on the second contact surface 104 of the winding substrate 1 is expanded into three, the number of the low-voltage windings 3 is expanded to 6, the winding method of the low-voltage winding 3 is the same as the winding method of the low-voltage winding 3 shown in the FIG. 1F, and details are not repeated here. The number of the high-voltage windings 2 is still 1, the two ends of the high-voltage windings 2 are electrically connected with the corresponding high-voltage AC terminals 4 respectively, and the high-voltage windings 2 sequentially penetrate through each winding region 701 in an S wiring mode and are coupled with each low-voltage winding 3. The three DC terminals 6 on the second contact surface 104 of the winding substrate 1 can be shorted on the second contact surface 104 and can also be shorted on the pin adapter board 11. If the number of the middle core leg 703b is two, the number of the side core leg 703a is correspondingly expanded, and the number of the side core leg 703a needs to be correspondingly expanded, and details are not described herein again. The high-voltage power semiconductor 901 can be designed as a half-bridge circuit topology, a full-bridge circuit topology and even a three-phase bridge circuit topology according to power requirements. The electric connection port arrangement on the first contact surface 103 of the winding substrate 1 is shown in FIG. 3B, and comprises six low-voltage AC terminals 5, two high-voltage AC terminals and an electric connection region 40, wherein the electric connection regions 40, the high-voltage AC terminals 4 and the low-voltage AC terminals 5 are sequentially arranged in the same direction, and the two high-voltage AC terminals 4 are arranged in the Y-axis direction. In the embodiment shown in FIG. 3C is different from the embodiment shown in FIG. 3B in that the two high-voltage AC terminals 4 are arranged in the X-axis direction. The electric connection ports can be designed according to actual application requirements, and are not limited thereto. The pins arranged on the fourth surface 11b of the lower substrate 11 are arranged as shown in FIG. 3D, wherein multiple input positive pins Vo+ and multiple ground pins GND are arranged in pairs, so that the requirement for uniform output of the large current of the power module Can be met.

Each of the aforementioned embodiments provides the advantages of the embodiment shown in Fig. 1A to FIG. 1J, and is standardized in expansion application, and easy to design, produce and apply. The embodiments are particularly suitable for an application in which the region on the corresponding client mainboard for the electric connection of the power module is relatively long and narrow, and the length of the lower substrate 11 is more than twice of the width of the lower substrate 11. For example, as shown in a top view of a client mainboard as shown in FIG. 3E, two long and narrow power modules and a large intelligent IC are placed on the same side of a client mainboard, and the two power modules are placed on the two opposite sides of the large intelligent IC respectively

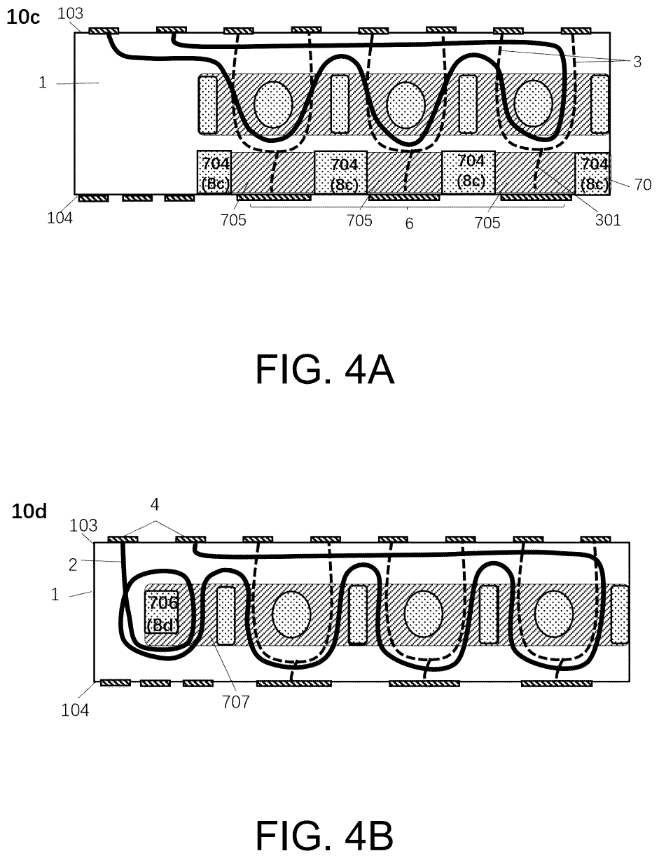

In some embodiment, as shown in FIG. 4A, the magnetic apparatus 10C further comprises an output inductor core 70 which is made of magnetically permeable material. The output inductor core 70 comprises two core plates and four core legs 704 respectively passing through four corresponding output-inductor holes 8c in the winding substrate 1, wherein regions between the output-inductor holes 8c are configured as output-inductor-winding regions 705. Two adjacent low-voltage windings 3 respectively pass through the corresponding winding regions 701 and are electrically connected with an extension line 301, which passes through the selected output-inductor-winding region 705 to form an output inductor L and is electrically connected with a corresponding DC terminal 6 arranged on the second contact surface 104 of the winding substrate 1. The magnetically permeable core 7 is coupled with the high-voltage winding 2 and a plurality of low-voltage windings 3 to form a plurality of tap center transformers, and the output inductor core 70 is coupled with a plurality of extension lines to form a plurality of output inductors. The center-tap transformers and output inductors are configured to have separated cores, while the center tap transformers and the output inductors are integrated on the same winding substrate, so that the center tap transformers and the output inductors are electrically connected in a one-to-one correspondence without adding welding spots. The number of turns of each secondary side winding of the center tap transformers is 0.5 turns, so that the volt-second integral and the inductance at the two ends of the inductors are greatly reduced. Since the inductance values are small, the magnetic apparatus 10c is suitable for applications with high dynamic response requirements. In addition, the magnetic apparatus 10c also provides the features that the high-voltage AC terminal 4 and the low-voltage AC terminal 5 are located on the first contact surface 103 of the winding substrate 1 and the DC terminal 6 is located on the opposite second contact surface, thereby the corresponding beneficial effects achieved.

In some embodiment, as shown in FIG. 4B, the magnetic apparatus 10d may be applied in an LLC resonant circuit topology. The magnetic apparatus 10d integrates the resonant inductors required by the LLC circuit topology in the magnetic apparatus. One side of the winding substrate 1 adjacent to the high-voltage AC terminal 3 is provided with a resonant-inductor hole 8d, a resonant inductor core leg 706 of the magnetically permeable core 7 passes through, the region between the resonant-inductor hole 8d and the adjacent magnetically-permeable-core hole 8a is defined as a resonant-inductor-winding region 707, the high-voltage winding 2 passes through the resonant-inductor-winding region 707 at least one time, at least one circle is wound around the resonant inductor core leg 706 to form a required resonant inductor, and the specific winding number can be designed according to actual requirements. In this embodiment, the resonant inductive core leg 706 is part of the magnetically permeable core 7, and the two magnetic substrates 702 are shared. In another embodiment, the resonant inductive core leg 706 can be combined with an independent magnetic substrate to form an independent resonant output inductive magnetically permeable core.

In some embodiment, the high-voltage winding 2 surrounds at least one circle of each middle core leg 703b, so that the number of turns of the high-voltage winding is greater than or equal to 1 turn, each low-voltage winding penetrates through a winding region 701 and is equivalently wound on the core leg 703b, and the number of turns is 0.5 turns. In other embodiments, the low-voltage winding 3 can also pass through the same winding region 701 multiple times, the number of turns of the low-voltage winding 3 is 1.5 turns or 2.5 turns (ie, N+0.5 turns, and N is a natural number.), so that the high-voltage AC terminal 4 and the low-voltage AC terminal 5 are both located on the first contact surface 103 of the winding substrate 1, and the DC terminal 6 is located on the opposite second contact surface 104, and the structural characteristics and the corresponding advantages of the magnetic apparatus 10 in the embodiment are maintained.

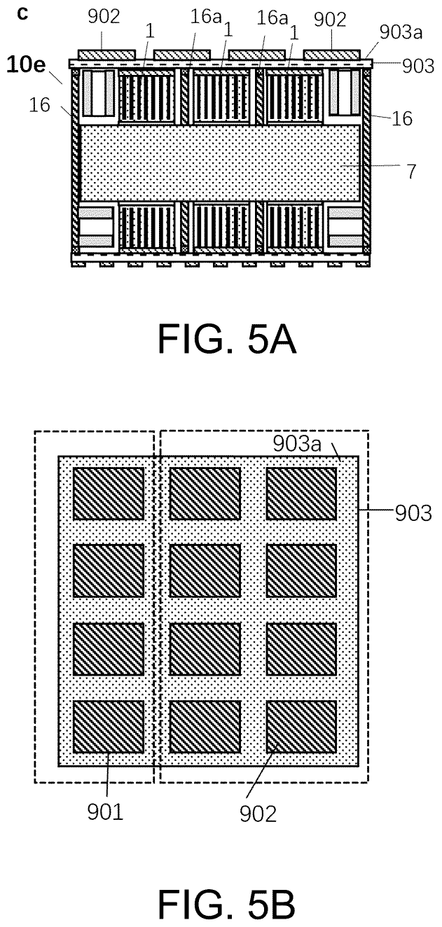

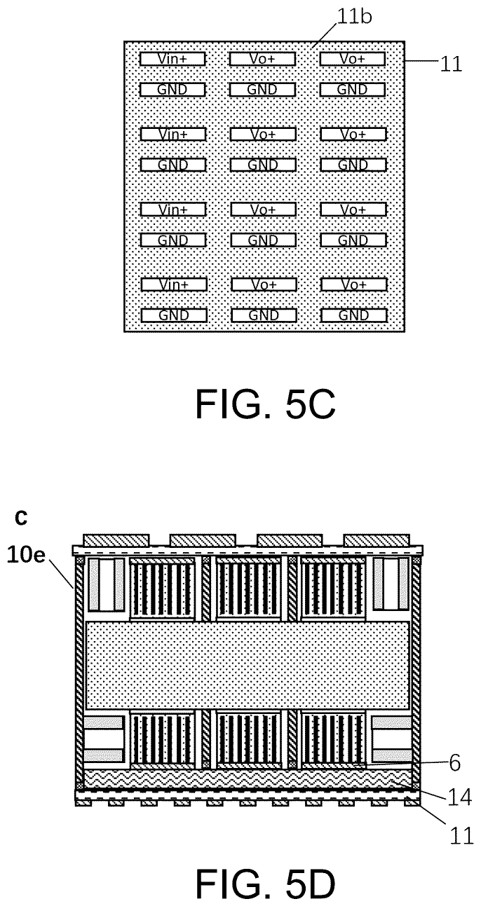

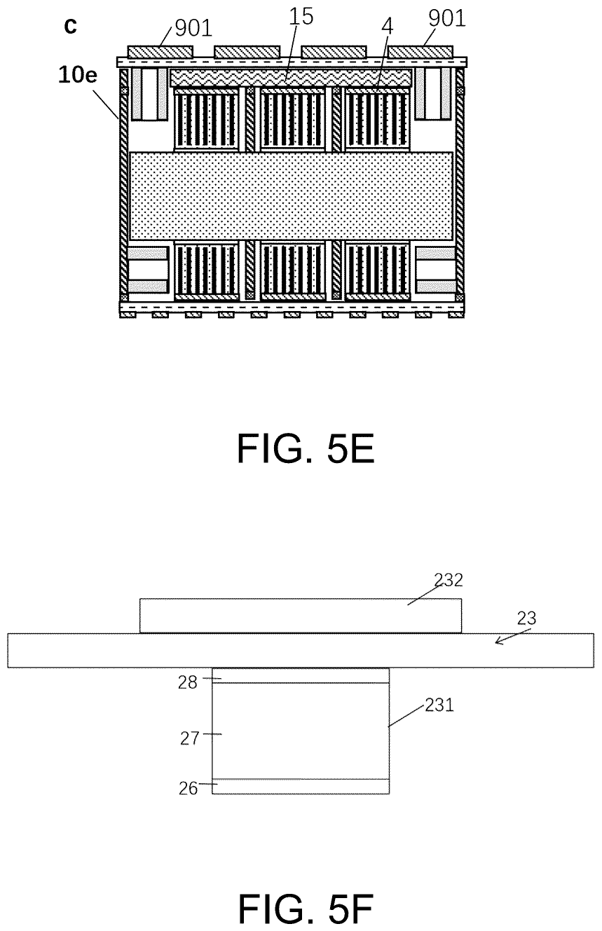

In some embodiments, as shown in FIG. 5A, referring to FIG. 1H, the power module C disclosed comprises a magnetic apparatus 10e, the magnetic apparatus 10e comprises a plurality of winding substrates 1 arranged side by side in the thickness direction of the winding substrate, the plurality of winding substrates 1 share one magnetically permeable core 7, a magnetically-permeable-core hole is provided at a corresponding position on each winding substrate 1, a vertical board 16a is provided between every two adjacent winding substrates 1, a penetrate structure is provided at a position on each vertical board 16a corresponding to the magnetically-permeable-core hole, and the magnetically-permeable-core holes, and the corresponding core legs of the magnetically permeable core 7 passing through. Each winding substrate 1 has the features of one of the winding substrates 1 as shown in the magnetic apparatus 10,10a-10d. The following is described by taking an embodiment wherein only one high-voltage winding 2 and two low-voltage windings 3 (referring to FIG. 1F) are provided in each of the winding substrates 1 as an example. A magnetic apparatus 10e has the same loading capacity with the magnetic apparatus 10b shown in FIG. 3A, but compared with the magnetic apparatus 10b, the side-by-side stacking structure of the magnetic apparatus 10e can further reduce the length of the power module. The winding substrate 1 is stacked side by side, so that the transmission current of the stacked assembly is large, and therefore, the vertical conductive connectors which are electrically connected with the upper assembly 26 and the power pins can be configured in the vertical boards 16a, so that the current transmission capability of the vertical board is improved, and at the same time, the large-current transmission loss is reduced. Meanwhile, each winding substrate 1 comprises a high-voltage winding 2 and two correspondingly coupled low-voltage windings 3, and high-efficiency conversion of the magnetic apparatus can be realized in a nearby coupling form, so that the high-voltage winding 2 on each winding substrate 1 is electrically connected to the upper assembly 26, and the upper assembly 26 is electrically connected in series or electrically connected in parallel. Two AC terminals 5 of two low voltage windings 3 on each winding substrate 1 are each electrically connected to the upper assembly 26 and are electrically connected in parallel through the upper assembly 26. One DC terminal 6 of the two low voltage windings 3 on each winding substrate 1 is electrically connected to the lower substrate 11, and is electrically connected in parallel by means of the lower substrate 11. FIG. 5B shows a layout of a plurality of switching devices on a first surface 903a of an upper substrate 903 of the power module C, and FIG. 5C shows a pin layout on a fourth surface 11 b of a lower substrate 11 of the power module C, wherein each input positive pin is matched with a ground pin GND to form staggered arrangement, each output positive pin is matched with a ground pin GND to form staggered arrangement, the parasitic resistance and parasitic inductance of the input pin and the output pin of the power module are reduced, the transmission loss of the power module is reduced, and the dynamic response performance of the power module is improved.

In some embodiments, as shown in FIG. 5D, the power module C can further comprise an output inductor 14, the output inductor 14 is arranged between the magnetic apparatus 10e and the lower substrate 11, and the DC terminal 6 is electrically connected with the output positive pin Vo+through the output inductor 14. The arrangement structure of the output inductor shown in FIG. 5d is also suitable for the application of the power module A and the power module B.

In some embodiments, as shown in FIG. 5E, the power module C may further comprise a resonant inductor 15, the resonant inductor 15 is disposed between the magnetic apparatus 10e and the upper assembly 26, and the high-voltage AC end 4 is electrically connected to the upper assembly 26 by means of the resonant inductor 15. The arrangement structure of the resonant inductor shown in FIG. 5E is also suitable for the application of the power module A and the power module B.

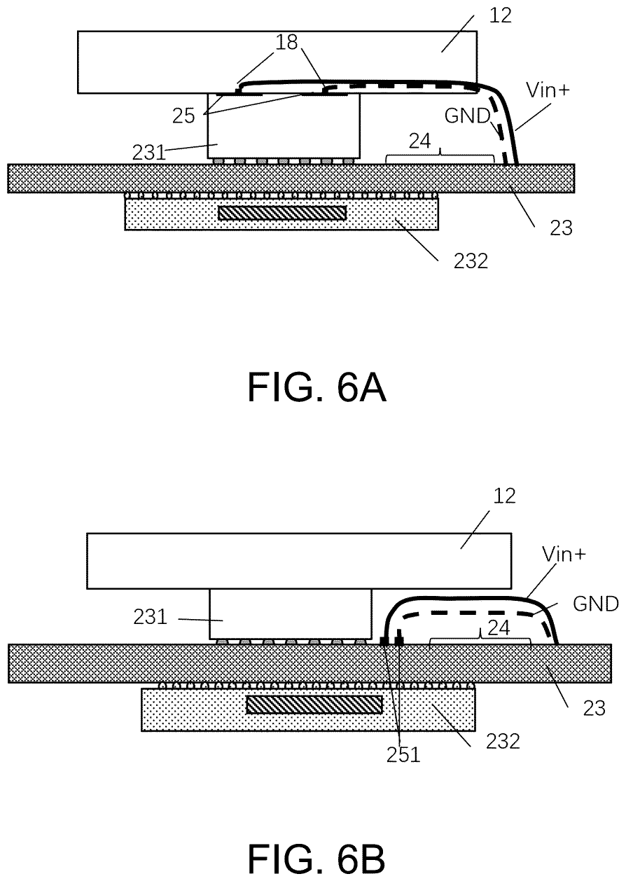

FIG. 5F and FIG. 6A show a power supply system, comprising a client mainboard 23, a large intelligent IC 232 and a power module 231. The large intelligent IC 232 is installed on one side of the client mainboard 23. The bottom of the large intelligent IC 232 comprises signal pins located on the periphery of the bottom and power supply pins surrounded by the signal pins. The large intelligent IC 232 power supply pin further comprises a power supply positive pin and a power supply negative pin, and the power supply positive pin and the power supply negative pin are arranged in a staggered mode. The large intelligent IC 232 signal pin is electrically connected to other devices on the system board through vias of the signal pin via hole region 24 on the system board. The power module 231 is mounted on the other side of the client mainboard 23, is opposite to the power supply pin of the intelligent chip, and provides direct current power supply for the large intelligent IC 232 through a via hole of a power supply pin via area (not shown) of the client mainboard 23. Some embodiments are particularly suitable for the situation that the large current pin arrangement area on the pin adapter plate 11 of the power supply module 231 is close to the output arrangement of the square, namely the aspect ratio of the large current pin arrangement area is smaller than 2. The power module 231 is placed under the large intelligent IC 232 of the client mainboard 23, a vertical power supply structure is adopted, the large-current transmission path is greatly reduced, the energy transmission efficiency is improved, the parasitic resistance and the parasitic inductance of the transmission path are reduced, and the dynamic response capability of the power module is improved.

As shown in FIG. 5F, the input power required by the power module 231 is transmitted to the power module 231 from the client mainboard 23. The input power is then transmitted from the lower assembly 28, through the second assembly 27, and to the power semiconductor device of the upper assembly 26; the output power of the power module 231 is transmitted to a large intelligent chip 232 through the lower assembly 28 and the client mainboard 23. However, since the area of mainboard 23 is limited and the input voltage is high, e.g., most of the input voltage is 12V, 48V, or even 400V-800V, the wiring within the client mainboard 23 is not suitable for the transmission of the input power especially when the input voltage is higher than 60V despite the relatively small input current; in the case of the input voltage lower than 60V, the requirement on the safety insulation distance of wiring on the client mainboard 23 is not quite high, while the wiring of the input power needs to laterally pass through the signal-via region 24 around the large intelligent chip 232 on the client mainboard 23, in which vias of the signal pins are arranged, so that gaps with a safety insulation distance is required between the wiring and the vias of the signal pins, and the specification of the signal pin pitch in conventional pin layouts does not meet the requirement of the safety insulation distance in the case of an input voltage of 40V-60V. In order to arrange the wiring off the signal-via region 24, in the embodiment as shown in FIG. 6A, the wiring of the input power is configured to pass through the heat dissipation device 12. The heat dissipation device 12 is arranged on the upper side of the upper assembly 26 of the power module 231, covering the upper substrate 903 and respectively in thermal connection with the high-voltage power semiconductor device 901 and the low-voltage power semiconductor device 902. The wiring of the input power is integrated in the heat dissipation device 12 as busbars (i.e., a set of input power supply lines comprises input positive wires and ground wires), power supply contacts 18 are arranged on the lower surface of the heat dissipation device 12, and one end of each of the busbars is fixed and electrically connected with the selected power supply contact 18. Correspondingly, input power contacts 25 (i.e., input positive pins Vin+ and ground pins GND) are arranged above the upper assembly 26. On the mounting of the heat dissipation device 12, the power supply contacts 18 is electrically connected with the input power contacts 25 to form reliable power supply. The other end of each of the busbars extends out of the heat dissipation device 12, electrically connected with the client mainboard 23 to receive the power supply from the client mainboard 23. The input power contacts 25 are not arranged on the lower substrate 11 but in contact connection with the heat dissipation device 12, so that the wiring of the input power does not pass through the gaps between the signal vias in the signal-via region 24, thereby providing a clearance distance of the high-voltage wiring without the limitation of the wiring layout of the client mainboard 23. In some embodiments, as shown in FIG. 6B, different from the aforementioned structure shown in FIG. 6A, the input power supply lines are fixedly and electrically connected to the client mainboard 23 outside the singal-via region 24 at one end, cross over the signal-via region 24, and are fixedly and electrically connected to connectors 251 provided on the client mainboard 23 in the region adjacent to the power module 231 at the other end. Therefore, the input power is transmitted to the lower substrate 11 of the power module 231 through a short-distance wiring over client mainboard 23 but does not pass through the signal-via region 24, and input power is supplied to the power module 231 through the input positive pins Vin+ and the ground pins GND arranged on the edge of the lower substrate 11. The conflict of the wiring of the input power and the pitch specification of the signal-via region 24 is effectively avoided.

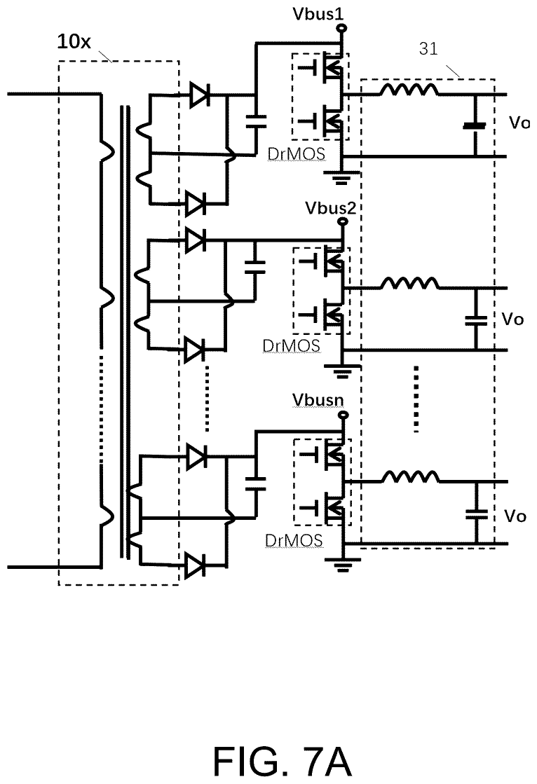

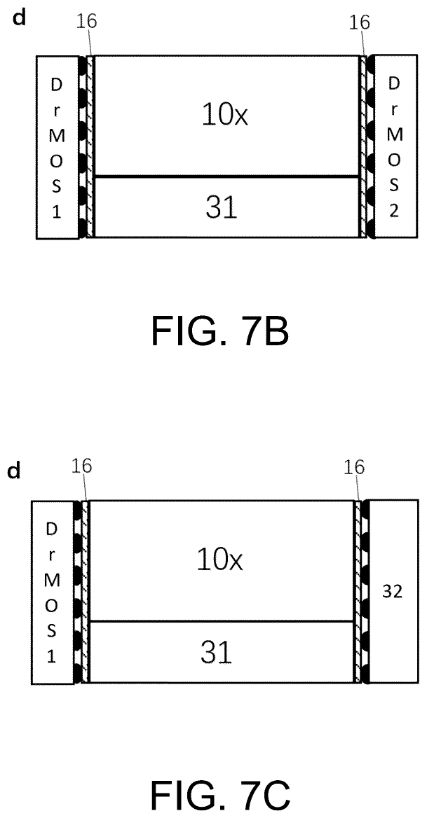

In some embodiments, the structure and layout of the upper assembly 26, the magnetic apparatus 10x and the vertical board 16 of the power module D can also be suitable for two-stage series voltage reduction power modules, and the circuit topology shown in FIG. 7A is connected in series with a first-stage buck circuit at the output end of a step-down circuit of the first-stage transformer. Each DC terminal 6 of the magnetic apparatus 10x provides energy to each rear-stage buck circuit. In this way, the energy transmission path from the step-down circuit with the transformer to the buck circuit is short, and the parasitic inductance and the parasitic resistance on the transmission path are greatly reduced. Moreover, because the transmission path is short, an intermediate capacitor with dual functions is configured to substitute for the output capacitor of the step-down circuit with the transformer and the input capacitor of the post-stage buck circuit (which are separately provided in the power module of prior arts), so that the size, loss and cost are further reduced.

In some embodiments, as shown in FIGS. 7B-7C (the upper assembly 26 and the lower substrate 11 are not shown). The magnetic apparatus 10x and the rear-stage passive circuit element array 31 are designed in an up-down stacking mode, and the intermediate capacitor (not shown in FIGS. 7B and 7C) can be arranged between the rear-stage passive circuit element array 31 and the magnetic apparatus 10x and can also be arranged around the magnetic apparatus 10x; one end of the intermediate capacitor is electrically connected with the corresponding DC terminal 6, and the other end of the intermediate capacitor serves as an intermediate bus end to be electrically connected with the corresponding low-voltage power semiconductor device 902 and the corresponding rear-stage power semiconductor DRMOS respectively.

In some embodiments, the at least one vertical board 16 is located on the side face of the stack formed by the rear-stage passive circuit element array 31, the intermediate capacitor and the magnetic apparatus 10x, the rear-stage power semiconductor DRMOS is arranged on the vertical board 16, and the DRMOS can dissipate heat through the side face. Each post-stage step-down module comprises at least one post-stage passive circuit element array 31 and at least one post-stage power semiconductor DRMOS, and two of the structures shown in FIG. 7B corresponding to a DC terminal 6 of a magnetic apparatus 10x are provided with DRMOS, while one side of the structure shown in FIG. 7C is provided with a DRMOS, and the other side of the structure can be provided with a controller unit 32 required by the power module.

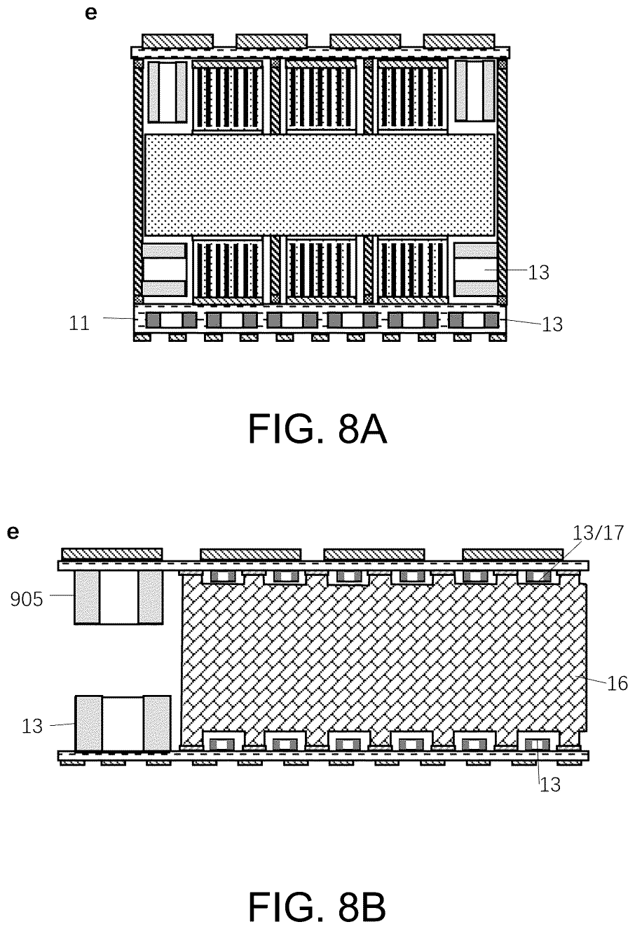

In some embodiments, how to place the power module E in a high-frequency capacitor arrangement mode as much as possible is shown. In some embodiments, the high-frequency capacitor comprises a high-voltage-high-frequency capacitor 905 and a low-voltage-high-frequency capacitor 13 as shown in FIGS. 8A and 8B, and the high-voltage-high-frequency capacitor 905 is arranged on the surface or inside the upper substrate 903; and the low-voltage-high-frequency capacitor 13 is arranged on the surface or the interior of the vertical board 16 or arranged on the surface or the interior of the lower substrate 11, and as shown in FIG. 8A, more low-voltage-high-frequency capacitors 13 can be buried in the lower substrate 11.

In some embodiments, as shown in FIG. 7B, when more output low-voltage capacitors need to be placed, the welding positions of the vertical board 16 and the lower substrate 11 can be cut into groove-shaped structures and pins which are alternately arranged, and more low-voltage high-frequency capacitors 13 are placed on the third surface 11a of the lower substrate 11 corresponding to the positions of the groove-shaped structures, so that the number and distribution of the electric connection ports are ensured, and the number of the low-voltage-high-frequency capacitors is increased. Similarly, more low-voltage-high-frequency capacitors 13 or auxiliary power supply capacitors 17 are placed on the second surface 903b of the upper substrate 903 and corresponding to the positions of the groove-shaped structures on the second surface 903b of the upper substrate 903, and the auxiliary power supply capacitor 17 herein can be electrically connected with auxiliary power supply of the high-voltage power semiconductor device 901 or auxiliary power supply of the low-voltage power semiconductor 902 to provide a filtering function for the auxiliary power supply.

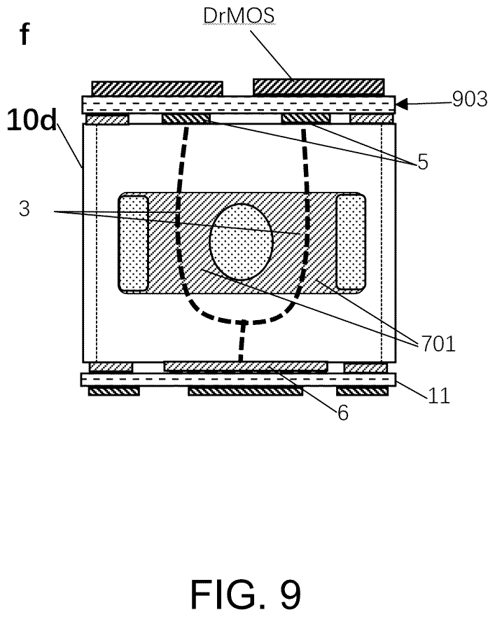

In some embodiments, the magnetic apparatus shown in the embodiment can also be applied to a BUCK step-down circuit, the BUCK step-down circuit can refer to a BUCK step-down circuit part in the circuit topology shown in FIG. 7A, and each phase BUCK step-down circuit comprises a DRMOS, an output inductor, an input capacitor and an output capacitor. In the embodiment, two-phase Buck circuits are connected in parallel to illustrate that the two-phase Buck circuits are similar to the side view structure schematic diagram of the power module A shown in FIG. 1F. The power module F also comprises an upper assembly 26, a second assembly 27 and a lower assembly 28. As shown in the side view structure schematic diagram shown in FIG. 9, the difference is that the two DRMOS of the power module F are arranged on the first surface 903a of the upper substrate 903, and the input capacitor is adjacent to the two DRMOS placement. The magnetic apparatus 10f only comprises two low-voltage windings 3, and one end of each low-voltage winding 3 is electrically connected to the AC terminal 5 of the first contact surface 103 of the winding substrate 1, so as to be electrically connected to the midpoint of the switch bridge arm of the DRMOS of the upper substrate 903; the other ends of the two low-voltage windings 3 are electrically connected to the DC terminal 6 of the second contact surface 104 of the winding substrate 1, each low-voltage winding 3 passes through the corresponding winding area 701, and the two low-voltage windings are magnetically coupled into two output inductors through the magnetically permeable core. The magnetic apparatus 10f also has the features and benefits of the previous embodiment, and can also be designed according to the extension embodiment.

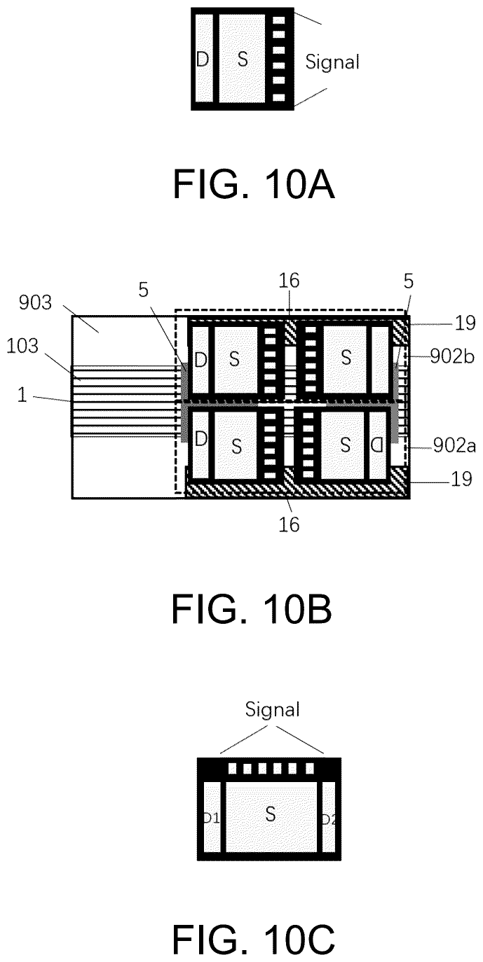

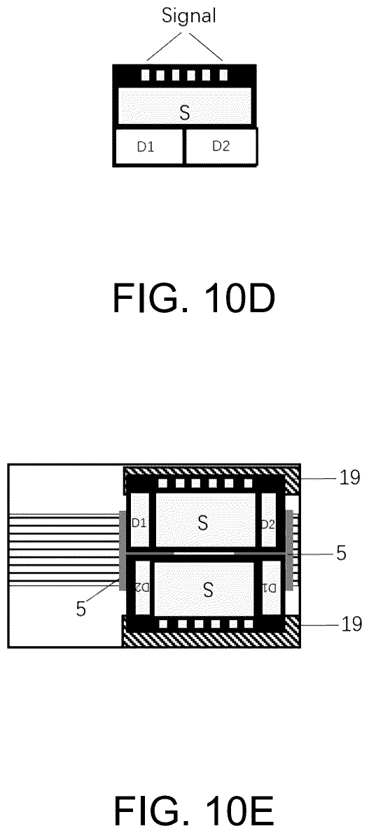

In some embodiments, as shown in FIG. 10A, the low-voltage power semiconductor device 902 is a synchronous-rectification single-switch encapsulation. The pin layout of the single-switch encapsulation includes a drain D, a source S and a signal pin region (marked as signal in FIG. 10A). The drain D, the source S and the signal pin region are sequentially arranged. The signal pin includes driving signal pins, current sampling pins, temperature sampling pins, and/or auxiliary power supply pins. The signal sampling devices and the semiconductor switches are integrated in the single-switch encapsulation, so that the number of peripheral devices and the space required thereby is effectively reduced. The arrangement of the single-switch encapsulations in the power module is shown in FIG. 10B. Four single-switch encapsulations are arranged on the upper substrate 903, each encapsulation including one switch devices. Two switch devices of every two encapsulations form a switch device group 902a or 902b. The switch device group 902a and 902b are arranged respectively along either edge of the winding substrate 1 and approximately in diagonal symmetry. In each switch device group, the signal pin regions of the two encapsulations are arranged near to each other, the two sources S are electrically connected with a same electric connection terminal 19 on a vertical board, and the two drains D are respectively electrically connected with the corresponding low-voltage AC terminal 5. The arrangement disclosed herein effectively shortens the loop path formed by the two synchronous rectification switch devices and the two low-voltage windings 3 in the switch device group 902a or 902b, reduces the alternating current parasitic resistance and the parasitic inductance, and improves the transmission efficiency of the power module.

In some embodiments, as shown in FIG. 10C, the low-voltage power semiconductor device 902 is a synchronous-rectification double-switch encapsulation; namely, two synchronous-rectification switch devices are integrated in one encapsulation, and the two synchronous rectification switch devices share a public source S (in some embodiments, the interconnection of the two sources is integrated in the encapsulation, while in other embodiments, two source pins are exposed on the surface of the encapsulation and electrically connected to form the public source S though wiring in the upper substrate assembly 26; the inventors consider the former better), the two drain D1 and D2 are respectively arranged on two opposite sides of the public source S. According to the pin layout, the loop path formed by the two synchronous rectification switch devices in the encapsulation and the two low-voltage windings 3 is minimized, the alternating current parasitic resistance and the parasitic inductance are reduced, and the transmission efficiency of the power module is improved. The signal pins include a plurality of signal pins, such as driving signal pins, current sampling pins, temperature sampling pins, auxiliary power supply pins and the like, and the signal pins are arranged along a third side of the public source S. The synchronous-rectification double-switch encapsulation shown in FIG. 10C is based on Trench MOSFETs, and the pin layout of an encapsulation based on planar MOSFETs is shown in FIG. 10D, the public source S of the two synchronous-rectification switch devices is arranged in the middle of a surface of the encapsulation, two drains D1 and D2 are arranged on one side of the public source S, and a signal pin region (marked as signal in FIG. 10C and 10D) is arranged on another side of the public source S. In some embodiments, as shown in FIG. 10E, the two synchronous-rectification double-switch encapsulations are arranged on the upper substrate 903 and are arranged respectively along either edge of the winding substrate 1 and approximately in diagonal symmetry. A first drain D1 of a first encapsulation and a second drain D2 of a second encapsulation are respectively electrically connected to a same AC terminal 5, and a second drain D2 of the first encapsulation and a first drain D1 of the second encapsulation are respectively electrically connected to another same AC terminal 5. The interconnected public source S is electrically connected to the electric connection terminal 19.

In order to minimize the volume of power module, a highly integrated semiconductor device is used, that is, synchronous rectification MOSFETs are integrated as the low-voltage power semiconductor. Multiple kinds of semiconductor devices are suitable for the aforementioned disclosure such as Silicon MOSFETs, SiC (Silicon Carbide) devices, GaN (Gallium Nitride) devices and the like. In some embodiment, two synchronous rectification driven MOSFETs are embedded in a PCB, the first drain pin, the second drain pin, the public source pin and the signal pins are arranged on the surface of the PCB, and the arrangement of the pins is as described in the aforementioned embodiments. In another embodiment, two synchronous rectification driven MOSFETs are plastically encapsulated in one plastic encapsulation, the plastic encapsulation material covers the two MOSFETs, and the first drain pin, the second drain pin, the public source pin and the signal pins are exposed on the surface of the plastic encapsulation with an arrangement as described in the aforementioned embodiments.

The aforementioned embodiments in this application may have the following beneficial effects:
(1) The magnetic apparatuses aforementioned are simple to manufacture, small in size and high in current density, integrate multiple circuit functional units such as resonant inductor, output inductors and a pin wiring, and is suitable for different application scenes of power supply;
(2) In some applications of converting a high voltage such as 48V to a low-voltage output such as 0.85V, the current output density per unit region in some of the aforementioned embodiments may be increased by 50%;
(3) The power modules are simple to assemble, the power supply devices are easily configured to have a proper length-width ratio according to the application scene, meanwhile, the height of the power module is minimized, and the size is minimized;
(4) With the symmetric arrangement of the multiple-switch encapsulation of the low-voltage power semiconductor devices, the current configured to transmit laterally on the surface of the upper substrate is minimized, so that the loss of the power module is minimized.

What is claimed is:

1. An apparatus, comprising:
a magnetically permeable core and a winding substrate;
wherein the winding substrate is provided with a first side surface and a second side surface which are opposite to each other, and the winding substrate is further provided with a first contact surface and a second contact surface which are opposite to each other;
wherein the first contact surface and the second contact surface are located between the first side surface and the second side surface; at least two AC terminals are arranged on the first contact surface; at least one DC terminal is arranged on the second contact surface; at least three penetrate structures are formed in the winding substrate and configured as magnetically-permeable-core holes, each of the penetrate structures penetrating from the first side surface to the second side surface; parts of the winding substrate between the magnetically-permeable-core holes are configured as winding regions;
wherein the magnetically permeable core comprises at least three core legs and two core plates; the core plates are affixed to the first side surface or the second side surface respectively; the core legs are connected to the core plates through the selected magnetically-permeable-core holes;
wherein at least two windings are arranged in the winding substrate, the windings passing through the selected winding region or the selected winding regions;
wherein one end of each of the windings is electrically connected with the selected AC terminal; and
wherein another end of each of the windings is electrically connected with the selected DC terminal.

2. The apparatus of claim 1, wherein at least two winding regions are provided, and at least two of the windings are configured as low-voltage windings, each of the low-voltage windings passing through one selected winding region; a high-voltage winding is further configured in the winding substrate, the high-voltage winding passing through each of the selected winding regions through which the low-voltage windings pass; and
wherein the AC terminals include two high-voltage AC terminals and at least one low-voltage AC terminal; two ends of the high-voltage winding are electrically connected with the high-voltage AC terminals, and two ends of each of the low-voltage windings are electrically connected with the selected low-voltage AC terminal and the selected the DC terminal respectively.

3. The apparatus of claim 2, wherein the high-voltage winding passes through at least one of the winding regions multiple times in a same direction, and a number of turns of the high-voltage winding is greater than 1.

4. The apparatus of claim 2, wherein the low-voltage windings are in an even number and are arranged in pairs, the low-voltage windings in each of the pairs respectively pass through the two winding regions separated by one of the core legs, and the low-voltage windings in each of the pairs are connected to one selected DC terminal.

5. The apparatus of claim 2, wherein at least two winding substrates are provided and are arranged side by side, the magnetically-permeable-core holes in one winding substrate are aligned with the magnetically-permeable-core holes in another winding substrate, and the core legs pass through the aligned magnetically-permeable-core holes;
wherein two low-voltage windings are configured in each of the winding substrates, the low-voltage windings in each of winding substrates respectively pass through the two winding regions separated by one of the core legs, and the low-voltage windings in each of the winding substrates are connected to one selected DC terminal; and
wherein the high-voltage winding in one of the winding substrates is electrically connected in series or in parallel to the high-voltage winding in another of the winding substrates.

6. The apparatus of claim 2, wherein at least two penetrate structures are further formed in the winding substrate and configured as output-inductor holes, each of the penetrate structures penetrating from the first side surface to the second side surface; parts of the winding substrate between the output-inductor holes are configured as output-inductor-winding regions; each of the low-voltage windings passes through the winding regions, passes through the output-inductor-winding regions, and is electrically connected with the DC terminal; and
wherein the magnetically permeable core further comprises an output inductor core, the output inductor core comprises output inductor core legs, and the output inductor core legs pass through the selected output-inductor holes.

7. The apparatus of claim 2, wherein a resonant-inductor hole is further formed in the winding substrate, the magnetically permeable core further comprises a resonant inductor core leg, the resonant inductor core leg passes through the resonant-inductor hole, and at least one part of the high-voltage winding is configured to wind around the resonant inductor core leg by at least one turn.

8. The apparatus of claim 1, wherein at least one electric connection region is further provided in the winding substrate, conductive connectors are configured in the electric connection region, first additional terminals are arranged on the first contact surface and second additional terminals are arranged on the second contact surface, and the first additional terminals are electrically connected with the selected second additional terminals through the conductive connectors; and
wherein the electric connection region is configured to transmit high-voltage DC input signals, and/or detection signals, and/or control signals, and/or auxiliary power supply signals between the first contact surface and the second contact surface,
and/or, the electric connection region is configured to extend ground pins between the second contact surface and the first contact surface.

9. The apparatus of claim 8, wherein each of the windings passes through the selected winding regions multiple times in a same direction.

10. A power module, comprising:
a middle assembly comprising a magnetically permeable core and a winding substrate;
an upper assembly comprising an upper substrate and one or more power semiconductor devices, wherein the power semiconductor device or each of the power semiconductor devices is arranged on the upper substrate, and
power pins comprising ground pins, input positive pins and output positive pins;
wherein the winding substrate is provided with a first side surface and a second side surface which are opposite to each other, and the winding substrate is further provided with a first contact surface and a second contact surface which are opposite to each other;
wherein the first contact surface and the second contact surface are located between the first side surface and the second side surface; at least two AC terminals are arranged on the first contact surface; at least one DC terminal is arranged on the second contact surface; at least three penetrate structures are formed in the winding substrate and configured as magnetically-permeable-core holes, each of the penetrate structures penetrating from the first side surface to the second side surface; parts of the winding substrate between the magnetically-permeable-core holes are configured as winding regions;
wherein the magnetically permeable core comprises at least three core legs and two core plates; the core plates are affixed to the first side surface or the second side surface respectively; the core legs are connected to the core plates through the selected magnetically-permeable-core holes;
wherein at least two windings are arranged in the winding substrate, the windings passing through the selected winding region or the selected winding regions;
wherein one end of each of the windings is electrically connected with the selected AC terminal;
wherein another end of each of the windings is electrically connected with the selected DC terminal;
wherein the middle assembly is arranged between the upper assembly and the power pins;
wherein the first contact surface is configured to face the upper substrate; and
wherein the power semiconductor device is electrically connected with the selected AC terminals, and the output positive pins are electrically connected with the selected DC terminal or the selected DC terminals.

11. The power module of claim 10 further comprising a heat dissipation device arranged above the upper assembly;
wherein the heat dissipation device is in thermal connection with the power semiconductor device, and a lower surface of the heat dissipation device covers the upper substrate; an input power supply line is arranged in the heat dissipation device; and one end of the input power supply line is fixed and electrically connected with the upper substrate, and another end of the input power supply line extends out at a surface position of the heat dissipation device, and the surface position is not overlapped with the upper substrate.

12. The power module of claim 10 further comprising one or more vertical boards; wherein the vertical board or each of the vertical boards is arranged in parallel to the middle assembly; the vertical board or at least one of the vertical boards comprises at least one conductive connector;
wherein the conductive connector is connected to the upper substrate through surface mount technology; and
wherein the ground pins are electrically connected with the upper assembly through the middle assembly or through the selected conductive connector or the selected conductive connectors; and the input positive pins are electrically connected with the upper assembly through the middle assembly or through the selected conductive connector or the selected conductive connectors.

13. The power module of claim 12, wherein at least one counterbore is formed in the upper substrate, the conductive connector is connected to the upper substrate at a position of the selected counterbore; and
wherein at least one via conductive connector is configured in the upper substrate; the via conductive connector is electrically connected with a bottom of the selected counterbore; and the via conductive connector is electrically connected with an upper surface of the upper substrate.

14. The power module of claim 12, wherein at least one throughbore is formed in the upper substrate, the conductive connector is connected to the upper substrate at a position of the selected throughbore.

15. The power module of claim 12, wherein the middle assembly comprises at least two parallel winding substrates; the vertical board or at least one of the vertical boards is arranged between the winding substrates.

16. The power module of claim 12, wherein the vertical board or at least one of the vertical boards comprises a controller and at least one low-voltage-high-frequency capacitor; wherein the low-voltage-high-frequency capacitor is electrically connected with the power semiconductor device; the low-voltage-high-frequency capacitor is configured as filter; and
wherein a groove-shaped structure is formed in an edge of the vertical board or at least one of the vertical boards, the low-voltage-high-frequency capacitor is located in the groove-shaped structure, and the low-voltage-high-frequency capacitor is electrically connected with the power semiconductor device; the low-voltage-high-frequency capacitor is configured as filter.

17. The power module of claim 10, wherein a plurality of power semiconductor devices are provided; the power semiconductor devices include a high-voltage power semiconductor device and at least one low-voltage power semiconductor device, the upper assembly further comprises a high-voltage-high-frequency capacitor, and/or the upper assembly further comprises a low-voltage-high-frequency capacitor;
wherein the high-voltage power semiconductor device and the low-voltage semiconductor device are electrically connected with the selected AC terminals; and
wherein the high-voltage-high-frequency capacitor is electrically connected with the high-voltage power semiconductor device, and the high-voltage-high-frequency capacitor is configured to provide alternating current for the high-voltage power semiconductor device; the low-voltage-high-frequency capacitor is electrically connected with the high-voltage power semiconductor device, or the low-voltage-high-frequency capacitor is electrically connected with the low-voltage power semiconductor device; the low-voltage-high-frequency capacitor is configured as filter.

18. The power module of claim 10 further comprising a lower substrate;
wherein the second contact surface is configured to face the lower substrate; the power pins are located on a surface of the lower substrate, and the output positive pins are electrically connected to the DC terminal through the lower substrate, the output positive pins and the ground pins are alternately arranged, and the input positive pins are arranged at an edge of the lower substrate; and
wherein at least one low-voltage-high-frequency capacitor is configured in the lower substrate; the low-voltage-high-frequency capacitor is electrically connected with the power semiconductor device; the low-voltage-high-frequency capacitor is configured as filter.

19. The power module of claim 12 further comprising a lower substrate;
wherein the second contact surface is configured to face the lower substrate; the vertical board is electrically connected to the lower substrate through surface mount technology; and
wherein at least one counterbore or at least one throughbore is formed in the lower substrate, the conductive connector is connected to the lower substrate at a position of the selected counterbore or the selected throughbore.

20. The power module of claim 10 further comprising a resonant inductor;
wherein the power semiconductor devices include a high-voltage power semiconductor device, the high-voltage power semiconductor device is electrically connected with the selected AC terminals through the resonant inductor.

21. The power module of claim 10 further comprising at least one output inductor;
wherein the output inductor is arranged between the magnetically permeable core and the second contact surface; at least a part of the DC terminal is electrically connected with the output positive pin through the output inductor.

22. The power module of claim 10, wherein the windings are in an even number and are arranged in pairs; the windings in each of the pairs respectively pass through the two winding regions separated by one of the core legs, and the windings in each of the pairs are connected to one selected DC terminal;
wherein the power semiconductor device or at least one of the power semiconductor devices comprises two switch groups electrically arranged in parallel; each switch group comprises two switch devices, at least one public source, a first drain and a second drain;
wherein the first drain and the second drain are configured for the electrically arranging in parallel; the windings in each of the pairs are respectively electrically connected with the first drain or the second drain in the selected switch group; and
wherein the switch groups are symmetrically arranged on an upper surface of the upper substrate by taking a position of the selected AC terminal as a center.

23. The power module of claim 12 further comprising intermediate capacitors and post-stage buck circuit modules electrically connected with the selected DC terminal or the selected DC terminals;
wherein each of the post-stage buck circuit modules comprises one or more post-stage passive devices and one or more post-stage power semiconductors;
wherein the post-stage passive devices are arranged between the middle assembly and the lower substrate; the selected intermediate capacitors are arranged between the post-stage passive devices and the middle assembly, and/or the selected intermediate capacitors are arranged around the middle assembly; and
wherein the vertical board or at least one of the vertical boards is arranged aside an assembly of the post-stage passive devices, the intermediate capacitors and the middle assembly; the post-stage power semiconductors are configured on the vertical board.

24. An encapsulation structure, comprising two switch devices, a first drain pin, a second drain pin, a public source pin, and at least one signal pin;
wherein the public source pin is electrically connected to a source of either of the switch devices;
wherein the first drain pin is electrically connected with a drain of one of the switch devices, and the second drain pin is electrically connected with a drain of another of the switch devices; and
wherein the signal pins are arranged on one side of the encapsulation structure; the signal pins are configured for transmitting driving signals, and/or reporting current signals, and/or reporting temperature signals, and/or auxiliary power supply.

25. The encapsulation structure of claim 24, wherein the first drain pin and the second drain pin are arranged on two sides of the public source pin, and the signal pins are arranged aside an array of the first drain pin, the public source pin and the second drain pin.

26. The encapsulation structure of claim 24, wherein the first drain pin and the second drain pin are arranged on one side of the public source pin, and the signal pins are arranged on another side of the public source pin.

27. The encapsulation structure of claim 24 further comprising a printed circuit board;
wherein the switch device is embedded in the printed circuit board; the first drain pin, the second drain pin, the public source pin and the signal pins are arranged on a surface of the printed circuit board.

28. The encapsulation structure of claim 24, wherein encapsulation material is disposed on the switch devices; the first drain electrode pin, the second drain electrode pin, the public source pin and the signal pin are exposed out of the encapsulation material.

29. A system, comprising: a system board, a chip, a power supply device, and at least one pair of input power supply lines;
wherein the input power supply lines include input positive wires and ground wires;
wherein the chip is installed on a surface of one side of the system board; signal pins and power supply pins are configured on a surface of the chip; the signal pins are arranged around the power supply pins; the power supply pins include power supply positive pins and power supply negative pins;
wherein the power supply device is installed opposite to the chip on a surface of another side of the system board; the power supply device is configured to provide direct current for the chip across the system board through vias; and
wherein the input power supply lines are configured to cross over a signal-via region of the system board; the input power supply lines are configured to provide power supply for the power supply device.

30. The system of claim 29, wherein one end of each of the input power supply lines is connected to the system board or a connector on the system board at a position out of the signal-via region.

31. The system of claim 30, wherein another end of each of the input power supply lines is connected to the system board or a connector on the system board at a position between the signal-via region and the power supply device.

32. The system of claim 30, wherein another end of each of the input power supply lines is connected to an upper surface of the power supply device.

33. The system of claim 32 further comprising a heat dissipation device arranged on the power supply device;
wherein the heat dissipation device is in thermal connection with the upper surface of the power supply device, and the input power supply lines penetrate through the heat dissipation device.

34. The system of claim 29, wherein the input power supply lines are configured to provide a voltage greater than or equal to 30V.
